(19) United States
(12) Patent Application Publication
(10) Pub. No.: US 2017/0222185 A1
(43) Pub. Date: Aug. 3, 2017

(54) ORGANIC ELECTROLUMINESCENT DISPLAY SUBSTRATE, ORGANIC ELECTROLUMINESCENT DISPLAY APPARATUS, AND METHOD FOR MANUFACTURING ORGANIC ELECTROLUMINESCENT DISPLAY APPARATUS

(71) Applicant: SHARP KABUSHIKI KAISHA, Sakai City, Osaka (JP)

(72) Inventors: Kazuki MATSUNAGA, Sakai City (JP); Katsuhiro KIKUCHI, Sakai City (JP); Shinichi KAWATO, Sakai City (JP); Takashi OCHI, Sakai City (JP); Satoshi INOUE, Sakai City (JP); Yuhki KOBAYASHI, Sakai City (JP); Eiichi MATSUMOTO, Mitsuke-shi (JP); Masahiro ICHIHARA, Mitsuke-shi (JP); Hirokazu SHIMEKI, Mitsuke-shi (JP)

(21) Appl. No.: 15/306,558

(22) PCT Filed: Apr. 17, 2015
(86) PCT No.: PCT/JP2015/061780

§ 371 Date: Oct. 25, 2016

(30) Foreign Application Priority Data
Apr. 25, 2014 (JP) 2014-091502
Sep. 18, 2014 (JP) 2014-190547

(51) Int. Cl. H01L 51/52; H01L 27/32; H01L 51/56; C23C 14/24

(52) U.S. Cl. CPC H01L 51/5259; C23C 14/24; H01L 27/3262; H01L 27/3258; H01L 51/56; H01L 27/3276

(57) ABSTRACT

An organic EL display substrate includes a light-emitting region containing a plurality of pixels and a getter member. The getter member is disposed in at least part of the area around the light-emitting region.

### TECHNICAL FIELD

The present disclosure relates to an organic electroluminescent (hereinafter also abbreviated to EL) display substrate, an organic EL display apparatus, a method for manufacturing an organic EL display apparatus, and an apparatus for manufacturing an organic EL display apparatus. More particularly, the present disclosure relates to an organic EL display substrate suitable for a large organic EL display apparatus, an organic EL display apparatus, a method for manufacturing an organic EL display apparatus, and an apparatus for manufacturing an organic EL display apparatus.

### BACKGROUND ART

In recent years, flat-panel display apparatuses have been used in various commodities and fields, and there has been a demand for larger flat-panel display apparatuses with improved image quality and lower power consumption.

Under these circumstances, organic EL display apparatuses that include an organic EL device utilizing electroluminescence of an organic material have attracted attention as improved flat-panel display apparatuses due to their all-solid state, low-voltage driving, high-speed responsivity, and self-luminosity.

Organic EL display apparatuses include an organic EL display substrate. The substrate includes a thin-film transistor (hereinafter also abbreviated to TFT) and an organic EL device coupled to the TFT, for example, on an insulating substrate, such as a glass substrate. Organic EL devices have a structure that includes a first electrode, an organic EL layer, and a second electrode stacked in this order. The first electrode is coupled to a TFT. The organic EL layer has a multilayer structure that includes a hole-injection layer, a hole-transport layer, an electron-blocking layer, a light-emitting layer, a hole-blocking layer, an electron-transport layer, and an electron-injection layer.

A vacuum deposition method or a coating method is mainly employed as a method for forming an organic EL layer. In the vacuum deposition method, an organic EL layer material is deposited onto a substrate with a vacuum deposition apparatus, such as a scanning deposition apparatus or an in-line deposition apparatus, to form an organic layer. In the coating method, a solution (ink) containing an organic EL layer material is applied to a substrate with a coating apparatus, such as an ink jet apparatus, and is dried with a vacuum apparatus to form an organic EL layer.

A method for manufacturing an organic EL device by the coating method disclosed (see, for example, Patent Literature 1) includes a vacuum apparatus preparing step of preparing a vacuum apparatus, which includes, for example, a vacuum chamber, a vacuum pump, an exhaust pipe for coupling the vacuum chamber to the vacuum pump, and a getter material disposed in the exhaust pipe; a pressure reducing step of placing a substrate, onto which a first electrode and an organic light-emitting layer material are disposed in this order, in the vacuum chamber, and reducing the internal pressure of the vacuum chamber with the vacuum pump; and a second electrode forming step of forming a second electrode above the organic light-emitting layer material subjected to the pressure reducing step, wherein the getter material contains the same material as the organic light-emitting layer material.

A method for detecting contaminants on a display substrate in which a metal pattern is formed on one or both faces of an insulating substrate is disclosed as a method for improving the yield in a process for manufacturing a display apparatus, such as an organic EL display apparatus (see, for example, Patent Literature 2).

### CITATION LIST

### Patent Literature

PTL 1: Japanese Unexamined Patent Application Publication No. 2013-222535

PTL 2: Japanese Unexamined Patent Application Publication No. 2013-200412

### SUMMARY OF INVENTION

### Technical Problem

However, organic EL devices manufactured by the vacuum deposition method with a scanning deposition apparatus or an in-line deposition apparatus have lower luminance than organic EL devices manufactured with a vacuum deposition apparatus in which vapor deposition is performed with a point evaporation source (point source) while a mask is in close contact with a substrate and while the substrate and mask are rotated (hereinafter also referred to as a rotary deposition apparatus). This is probably due to the following reasons. With scanning deposition apparatuses and in-line deposition apparatuses, vapor deposition treatment is performed while a substrate or an evaporation source is conveyed (scanned). Thus, scanning deposition apparatuses and in-line deposition apparatuses include more driving parts than rotary deposition apparatuses. Grease applied to these driving parts is scattered around a vapor deposition chamber (vacuum chamber) during evacuation, heating, or conveyance. Such a scattered grease component causes contamination (hereinafter also abbreviated to “contami”) and adheres to a substrate surface, thereby lowering luminance.

Patent Literature 1 discloses means for solving the problems in a printing method, but does not disclose means for solving the problems in the vacuum deposition method. Furthermore, Patent Literature 1 focuses only on impurities scattering from a vacuum pump, and does not focus on contamination in a vacuum chamber of a vacuum deposition apparatus.

Even if the technical idea described in Patent Literature 1 is applied to the vacuum deposition method, and, for example, a getter material is placed in an exhaust pipe of a vacuum pump in a vacuum deposition apparatus, the following problems remain. The getter material in the exhaust pipe mainly adsorbs impurities scattering from the vacuum pump, and contamination in a vacuum chamber of the vacuum deposition apparatus may be deposited onto a substrate. If the adsorptivity of the getter material decreases, and the getter material has high heat resistance, the exhaust pipe can be heated to remove impurities from the getter material by sublimation. However, if the getter material has low heat resistance, the exhaust pipe including the getter material must be replaced, or the exhaust pipe must be removed, and another getter material must be applied to the exhaust pipe. Furthermore, the getter material in the exhaust pipe affects evacuation, and evacuation of both the exhaust pipe containing the contaminated getter material and the vacuum chamber requires a large exhaust system.

Patent Literature 2 discloses a technique for examining the contamination status of a substrate but does not disclose means for solving the problems in the vacuum deposition method.

Thus, there is a room for improvement in the vacuum deposition method in order to reduce the effects of contamination and suppress a decrease in luminance.

In view of such situations, it is an object of the embodiment of the invention to provide an organic EL display substrate, an organic EL display apparatus, a method for manufacturing an organic EL display apparatus, and an apparatus for manufacturing an organic EL display apparatus, which can suppress a decrease in luminance in a vacuum deposition method.

### Solution to Problem

One aspect of the embodiment of the invention may be an organic electroluminescent display substrate, which includes a light-emitting region and a getter member. The light-emitting region contains a plurality of pixels. The getter member is disposed in at least part of the area around the light-emitting region and can adsorb contamination.

This organic electroluminescent display substrate is hereinafter also referred to as an organic EL display substrate according to the present invention.

Another aspect of the embodiment of the invention may be an organic electroluminescent display apparatus including an organic EL display substrate according to the present invention.

Another aspect of the embodiment of the invention may be a method for manufacturing an organic electroluminescent display apparatus, the method including

a vapor deposition step of depositing a material released from an evaporation source onto an organic EL display substrate according to the present invention while conveying at least one of the organic EL display substrate according to the present invention and the evaporation source to move the organic EL display substrate according to the present invention relative to the evaporation source, the evaporation source being configured to vaporize and release the material,

wherein in the vapor deposition step, the at least one of the organic EL display substrate according to the present invention and the evaporation source is conveyed such that the getter member faces the evaporation source before the light-emitting region faces the evaporation source.

This manufacturing method is hereinafter also referred to as a first manufacturing method according to the present invention.

Another aspect of the embodiment of the invention is an apparatus for manufacturing an organic electroluminescent display apparatus including an evaporation source, the evaporation source being configured to vaporize and release a material,

wherein the manufacturing apparatus deposits the material released from the evaporation source onto an organic EL display substrate according to the present invention while conveying at least one of the organic EL display substrate according to the present invention and the evaporation source to move the organic EL display substrate according to the present invention relative to the evaporation source, and

the at least one of the organic EL display substrate according to the present invention and the evaporation source is conveyed such that the getter member faces the evaporation source before the light-emitting region faces the evaporation source.

This manufacturing apparatus is hereinafter also referred to as a first manufacturing apparatus according to the present invention.

Preferred embodiments of an organic EL display substrate according to the present invention, the organic electroluminescent display apparatus described above, a first manufacturing method according to the present invention, and a first manufacturing apparatus according to the present invention will be described below. These preferred embodiments may be appropriately combined. Combinations of two or more of these preferred embodiments also constitute preferred embodiments.

The getter member may contain at least one material selected from the group consisting of aluminum (Al), copper (Cu), molybdenum (Mo), titanium (Ti), silicon (Si), silicon nitride, organic resins, positive electrode materials, hole-injection layer materials, hole-transport layer materials, and light-emitting layer materials.

The getter member may be disposed across the full width of the light-emitting region.

The getter member may be disposed in at least two portions of the area around the light-emitting region, the two portions facing each other with the light-emitting region interposed therebetween.

The getter member may be disposed in the entire area around the light-emitting region.

An organic EL display substrate according to the present invention may include a plurality of the light-emitting regions. The getter member may be disposed in at least part of the area around each of the light-emitting regions.

The getter member may have a rough surface.

An organic EL display substrate according to the present invention may have a micropattern of the getter member.

The getter member may be electrically insulated and may be separated from the light-emitting region.

Another aspect of the embodiment of the invention may be a method for manufacturing an organic electroluminescent display apparatus, the method including

a step of preparing a getter substrate including a getter member, the getter member being configured to adsorb contamination, and

a vapor deposition step of performing vapor deposition on an organic electroluminescent display substrate in a vapor deposition chamber after the getter substrate is placed in the vapor deposition chamber.

This manufacturing method is hereinafter also referred to as a second manufacturing method according to the present invention.

Preferred embodiments of the second manufacturing method according to the present invention will be described below.

After the getter substrate in the vapor deposition chamber is conveyed from the vapor deposition chamber, the organic electroluminescent display substrate may be conveyed into the vapor deposition chamber and may be subjected to the vapor deposition.

The organic electroluminescent display substrate may follow behind the getter substrate in the vapor deposition chamber.

The getter member may contain at least one material selected from the group consisting of aluminum (Al), copper (Cu), molybdenum (Mo), titanium (Ti), silicon (Si), silicon nitride, organic resins, positive electrode materials, hole-injection layer materials, hole-transport layer materials, and light-emitting layer materials.

Another aspect of the embodiment of the invention may be an apparatus for manufacturing an organic electroluminescent display apparatus including a vapor deposition chamber,

wherein the manufacturing apparatus performs vapor deposition on an organic electroluminescent display substrate in the vapor deposition chamber after a getter substrate including a getter member is placed in the vapor deposition chamber, the getter member being configured to adsorb contamination.

This manufacturing apparatus is hereinafter also referred to as a second manufacturing apparatus according to the present invention.

Preferred embodiments of the second manufacturing apparatus according to the present invention will be described below.

In the second manufacturing apparatus according to the present invention, vapor deposition on the organic electroluminescent display substrate may be performed after the getter substrate in the vapor deposition chamber is conveyed from the vapor deposition chamber and after the organic electroluminescent display substrate is conveyed into the vapor deposition chamber.

In the second manufacturing apparatus according to the present invention, vapor deposition may be performed while the organic electroluminescent display substrate follows behind the getter substrate in the vapor deposition chamber.

The getter member may contain at least one material selected from the group consisting of aluminum (Al), copper (Cu), molybdenum (Mo), titanium (Ti), silicon (Si), silicon nitride, organic resins, positive electrode materials, hole-injection layer materials, hole-transport layer materials, and light-emitting layer materials.

Another aspect of the embodiment of the invention is a method for manufacturing an organic electroluminescent display apparatus, the method including

a vapor deposition step of depositing a material released from an evaporation source onto an organic electroluminescent display substrate including a light-emitting region containing a plurality of pixels while conveying either the organic electroluminescent display substrate and a relative moving portion in a vapor deposition chamber or the evaporation source or both to move the organic electroluminescent display substrate and the relative moving portion relative to the evaporation source, the evaporation source being configured to vaporize and release the material,

wherein in the vapor deposition step, either the organic electroluminescent display substrate and the relative moving portion or the evaporation source or both are conveyed such that a getter member faces the evaporation source before the light-emitting region faces the evaporation source, the getter member being disposed in at least part of an area around the light-emitting region and being configured to adsorb contamination, and

the getter member is disposed on the relative moving portion.

This manufacturing method is hereinafter also referred to as a third manufacturing method according to the present invention.

Another aspect of the embodiment of the invention may be an apparatus for manufacturing an organic electroluminescent display substrate,

wherein the organic electroluminescent display substrate includes a light-emitting region containing a plurality of pixels,

the manufacturing apparatus includes a vapor deposition chamber, an evaporation source, a relative moving portion in the vapor deposition chamber, and a getter member to adsorb contamination, the evaporation source being configured to vaporize and release a material, the getter member being disposed in at least part of an area around the light-emitting region,

the material released from the evaporation source is deposited onto the organic electroluminescent display substrate while either the organic electroluminescent display substrate and the relative moving portion or the evaporation source or both are conveyed to move the organic electroluminescent display substrate and the relative moving portion relative to the evaporation source,

either the organic electroluminescent display substrate and the relative moving portion or the evaporation source or both are conveyed such that the getter member faces the evaporation source before the light-emitting region faces the evaporation source, and

the getter member is disposed on the relative moving portion.

This manufacturing apparatus is hereinafter also referred to as a third manufacturing apparatus according to the present invention.

Preferred embodiments of the third manufacturing method according to the present invention and the third manufacturing apparatus according to the present invention will be described below. These preferred embodiments may be appropriately combined. Combinations of two or more of these preferred embodiments also constitute preferred embodiments.

The relative moving portion may include an anti-adhesion plate disposed in at least part of the area around the organic electroluminescent display substrate.

The relative moving portion may include an electrostatic chuck that is larger than the organic electroluminescent display substrate.

The relative moving portion may include a transfer tray that is larger than the organic electroluminescent display substrate.

The getter member may contain at least one material selected from the group consisting of aluminum (Al), copper (Cu), molybdenum (Mo), titanium (Ti), silicon (Si), silicon nitride, organic resins, positive electrode materials, hole-injection layer materials, hole-transport layer materials, and light-emitting layer materials.

The getter member may be disposed across the full width of the light-emitting region.

The getter member may be disposed in at least two portions of the area around the light-emitting region, the two portions facing each other with the light-emitting region interposed therebetween.

The getter member may be disposed in the entire area around the light-emitting region.

The getter member may have a rough surface.

The getter member may have a micropattern.

The getter member may be disposed across the full width of the organic electroluminescent display substrate.

The getter member may be disposed in at least two portions of the area around the organic electroluminescent display substrate, the two portions facing each other with the organic electroluminescent display substrate interposed therebetween.

The getter member may be disposed in the entire area around the organic electroluminescent display substrate.

### Advantageous Effects of Invention

The embodiment of the invention can provide an organic EL display substrate, an organic EL display apparatus, a method for manufacturing an organic EL display apparatus, and an apparatus for manufacturing an organic EL display apparatus, which can suppress a decrease in luminance in a vacuum deposition method.

### BRIEF DESCRIPTION OF DRAWINGS

FIG. 1 is a schematic cross-sectional view of an organic EL display apparatus according to a first embodiment.

FIG. 2 is a schematic plan view of a structure in a light-emitting region of the organic EL display apparatus illustrated in FIG. 1.

FIG. 3 is a schematic cross-sectional view of an organic EL display substrate of the organic EL display apparatus illustrated in FIG. 1 and corresponds to a cross section taken along the line A-B of FIG. 2.

FIG. 4 is a flow chart illustrating a process for manufacturing the organic EL display apparatus according to the first embodiment.

FIG. 5 is a schematic view illustrating a light-emitting layer deposition step in a method for manufacturing the organic EL display apparatus according to the first embodiment and illustrating an apparatus for manufacturing the organic EL display apparatus according to the first embodiment and is a perspective view of an organic EL display substrate according to the first embodiment and an apparatus for manufacturing the organic EL display apparatus according to the first embodiment.

FIG. 6 is a schematic view illustrating a light-emitting layer deposition step in a method for manufacturing the organic EL display apparatus according to the first embodiment and illustrating an apparatus for manufacturing the organic EL display apparatus according to the first embodiment and is a cross-sectional view of an organic EL display substrate according to the first embodiment and an apparatus for manufacturing the organic EL display apparatus according to the first embodiment.

FIG. 7 is a schematic plan view of the organic EL display substrate according to the first embodiment.

FIG. 8 is a schematic view illustrating a light-emitting layer deposition step in a method for manufacturing an organic EL display apparatus according to Comparative Embodiment 1 and is a cross-sectional view of an organic EL display substrate and a scanning deposition apparatus.

FIG. 9 is a schematic plan view of an organic EL display substrate according to a modified example of the first embodiment.

FIG. 10 is a schematic view illustrating a light-emitting layer deposition step in a method for manufacturing an organic EL display apparatus according to a modified example of the first embodiment and illustrating an apparatus for manufacturing an organic EL display apparatus according to the modified example of the first embodiment and is a cross-sectional view of the organic EL display substrate according to the modified example of the first embodiment and an apparatus for manufacturing an organic EL display apparatus according to the modified example of the first embodiment.

FIG. 11 is a schematic plan view of an organic EL display substrate according to a modified example of the first embodiment.

FIG. 12 is a schematic plan view of an organic EL display substrate according to a modified example of the first embodiment.

FIG. 13 is a schematic plan view of an organic EL display substrate according to a second embodiment.

FIG. 14 is a schematic cross-sectional view of the organic EL display substrate according to the second embodiment.

FIG. 15 is a schematic cross-sectional view of a getter member in the organic EL display substrate according to the second embodiment.

FIG. 16 is a schematic cross-sectional view of a getter member in the organic EL display substrate according to the second embodiment.

FIG. 17 is a schematic plan view of the organic EL display substrate according to the second embodiment.

FIG. 18 is a schematic plan view of the organic EL display substrate according to the second embodiment.

FIG. 19 is a schematic cross-sectional view of the organic EL display substrate according to the second embodiment.

FIG. 20 is a schematic plan view of the organic EL display substrate according to the second embodiment.

FIG. 21 is a schematic plan view of an organic EL display substrate according to a third embodiment.

FIG. 22 is a schematic view illustrating a light-emitting layer deposition step in a method for manufacturing an organic EL display apparatus according to a fourth embodiment and illustrating an apparatus for manufacturing an organic EL display apparatus according to the fourth embodiment and is a cross-sectional view of an organic EL display substrate according to the fourth embodiment and the apparatus for manufacturing an organic EL display apparatus according to the fourth embodiment.

FIG. 23 is a schematic plan view of a getter substrate for use in a vapor deposition step in a method for manufacturing an organic EL display apparatus according to a fifth embodiment and for use in an apparatus for manufacturing an organic EL display apparatus according to the fifth embodiment.

FIG. 24 is a schematic view illustrating a light-emitting layer deposition step in the method for manufacturing an organic EL display apparatus according to the fifth embodiment and illustrating the apparatus for manufacturing an organic EL display apparatus according to the fifth embodiment and is a cross-sectional view of a getter substrate and the apparatus for manufacturing an organic EL display apparatus according to the fifth embodiment.

FIG. 25 is a schematic view illustrating the light-emitting layer deposition step in the method for manufacturing an organic EL display apparatus according to the fifth embodiment and illustrating the apparatus for manufacturing an organic EL display apparatus according to the fifth embodiment and is a cross-sectional view of an organic EL display substrate according to the fifth embodiment and the apparatus for manufacturing an organic EL display apparatus according to the fifth embodiment.

FIG. 26 is a schematic view illustrating the light-emitting layer deposition step in the method for manufacturing an organic EL display apparatus according to the fifth embodiment and illustrating the apparatus for manufacturing an organic EL display apparatus according to the fifth embodiment and is a cross-sectional view of a getter substrate, the organic EL display substrate according to the fifth embodiment, and the apparatus for manufacturing an organic EL display apparatus according to the fifth embodiment.

FIG. 27 is a schematic plan view of a getter substrate for use in the vapor deposition step in the method for manufacturing an organic EL display apparatus according to the fifth embodiment and for use in the apparatus for manufacturing an organic EL display apparatus according to the fifth embodiment.

FIG. 28 is a schematic plan view of a getter substrate for use in the vapor deposition step in the method for manufacturing an organic EL display apparatus according to the fifth embodiment and for use in the apparatus for manufacturing an organic EL display apparatus according to the fifth embodiment.

FIG. 29 is a schematic view illustrating a vapor deposition step in a method for manufacturing an organic EL display apparatus according to a sixth embodiment and illustrating an apparatus for manufacturing an organic EL display apparatus according to the sixth embodiment and is a cross-sectional view of an organic EL display substrate according to the sixth embodiment and the apparatus for manufacturing an organic EL display apparatus according to the sixth embodiment.

FIG. 30 is a schematic plan view of the organic EL display substrate according to the sixth embodiment.

FIG. 31 is a schematic plan view of a mask for use in the vapor deposition step in the method for manufacturing an organic EL display apparatus according to the sixth embodiment and provided in the apparatus for manufacturing an organic EL display apparatus according to the sixth embodiment.

FIG. 32 is a schematic plan view of a getter substrate for use in the vapor deposition step in the method for manufacturing an organic EL display apparatus according to the sixth embodiment and for use in the apparatus for manufacturing an organic EL display apparatus according to the sixth embodiment.

FIG. 33 is a schematic plan view of a mask for use in the vapor deposition step in the method for manufacturing an organic EL display apparatus according to the sixth embodiment and provided in the apparatus for manufacturing an organic EL display apparatus according to the sixth embodiment.

FIG. 34 is a schematic plan view of an organic EL display substrate according to the sixth embodiment.

FIG. 35 is a schematic plan view of a mask for use in the vapor deposition step in the method for manufacturing an organic EL display apparatus according to the sixth embodiment and provided in the apparatus for manufacturing an organic EL display apparatus according to the sixth embodiment.

FIG. 36 is a schematic view illustrating a light-emitting layer deposition step in the method for manufacturing an organic EL display apparatus according to the sixth embodiment and illustrating the apparatus for manufacturing an organic EL display apparatus according to the sixth embodiment and is a cross-sectional view of a getter substrate, the organic EL display substrate according to the sixth embodiment, and the apparatus for manufacturing an organic EL display apparatus according to the sixth embodiment.

FIG. 37 is a schematic view illustrating a light-emitting layer deposition step in a method for manufacturing an organic EL display apparatus according to a seventh embodiment and illustrating an apparatus for manufacturing an organic EL display apparatus according to the seventh embodiment and is a cross-sectional view of an organic EL display substrate and the apparatus for manufacturing an organic EL display apparatus according to the seventh embodiment.

FIG. 38 is a schematic view illustrating the light-emitting layer deposition step in the method for manufacturing an organic EL display apparatus according to the seventh embodiment and illustrating the apparatus for manufacturing an organic EL display apparatus according to the seventh embodiment and is a plan view of the organic EL display substrate and the apparatus for manufacturing an organic EL display apparatus according to the seventh embodiment.

FIG. 39 is a schematic view illustrating a light-emitting layer deposition step in a method for manufacturing an organic EL display apparatus according to Comparative Embodiment 2 and is a cross-sectional view of an organic EL display substrate and a scanning deposition apparatus.

FIG. 40 is a schematic view illustrating a light-emitting layer deposition step in a method for manufacturing an organic EL display apparatus according to a modified example of the seventh embodiment and illustrating an apparatus for manufacturing an organic EL display apparatus according to the modified example of the seventh embodiment and is a plan view of an organic EL display substrate and the apparatus for manufacturing an organic EL display apparatus according to the modified example of the seventh embodiment.

FIG. 41 is a schematic view illustrating a light-emitting layer deposition step in a method for manufacturing an organic EL display apparatus according to a modified example of the seventh embodiment and illustrating an apparatus for manufacturing an organic EL display apparatus according to the modified example of the seventh embodiment and is a plan view of an organic EL display substrate and the apparatus for manufacturing an organic EL display apparatus according to the modified example of the seventh embodiment.

FIG. 42 is a schematic view illustrating a light-emitting layer deposition step in a method for manufacturing an organic EL display apparatus according to a modified example of the seventh embodiment and illustrating an apparatus for manufacturing an organic EL display apparatus according to the modified example of the seventh embodiment and is a plan view of an organic EL display substrate and the apparatus for manufacturing an organic EL display apparatus according to the modified example of the seventh embodiment.

FIG. 43 is a schematic view illustrating a light-emitting layer deposition step in a method for manufacturing an organic EL display apparatus according to an eighth embodiment and illustrating an apparatus for manufacturing an organic EL display apparatus according to the eighth embodiment and is a plan view of an organic EL display substrate and the apparatus for manufacturing an organic EL display apparatus according to the eighth embodiment.

FIG. 44 is a schematic view illustrating a light-emitting layer deposition step in a method for manufacturing an organic EL display apparatus according to a ninth embodiment and illustrating an apparatus for manufacturing an organic EL display apparatus according to the ninth embodiment and is a plan view of an organic EL display substrate and the apparatus for manufacturing an organic EL display apparatus according to the ninth embodiment.

### DESCRIPTION OF EMBODIMENTS

The embodiment of the invention will be further described in the following embodiments with reference to the accompanying drawings. However, the embodiment of the invention is not limited to these embodiments.

### First Embodiment

The present embodiment describes an organic EL display apparatus of a bottom emission type for RGB full-color display, in which light is extracted through a TFT substrate. The present embodiment also describes a method for manufacturing the organic EL display apparatus. The present embodiment is also applicable to an organic EL display apparatus of another type and a method for manufacturing the organic EL display apparatus.

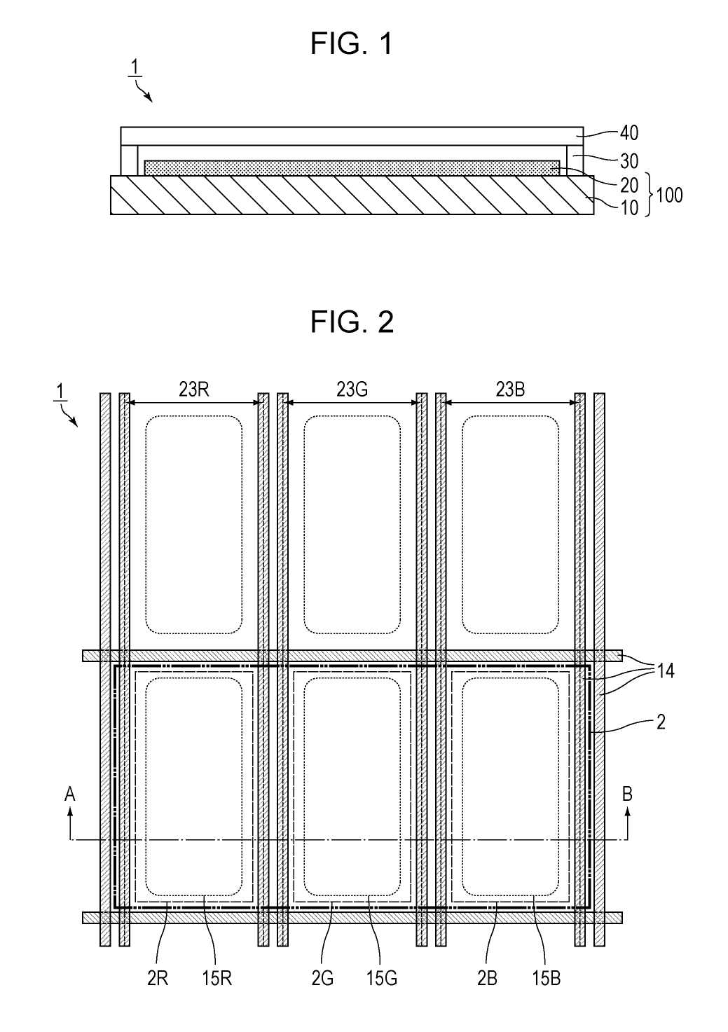

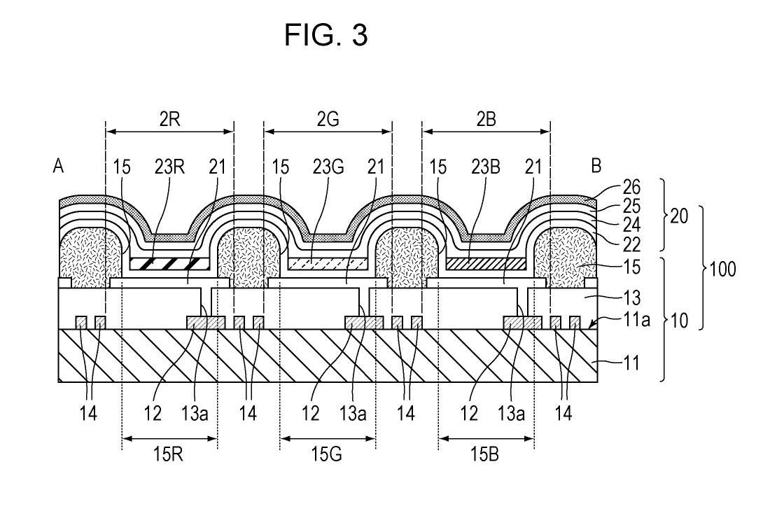

The overall structure of the organic EL display apparatus according to the present embodiment will be described below. FIG. 1 is a schematic cross-sectional view of the organic EL display apparatus according to the first embodiment. FIG. 2 is a schematic plan view of a structure in a light-emitting region of the organic EL display apparatus illustrated in FIG. 1. FIG. 3 is a schematic cross-sectional view of an organic EL display substrate of the organic EL display apparatus illustrated in FIG. 1 and corresponds to a cross section taken along the line A-B of FIG. 2.

As illustrated in FIG. 1, an organic EL display apparatus 1 according to the present embodiment includes an organic EL display substrate 100, an adhesive layer 30 on the periphery of the substrate 100, a sealing substrate 40 on the adhesive layer 30, and a getter member (not shown). The substrate 100 includes a TFT substrate 10 including a TFT 12 (see FIG. 3) and an organic EL device 20 disposed on the TFT substrate 10 and coupled to the TFT 12. The sealing substrate 40 faces the substrate 100 and covers the organic EL device 20. The adhesive layer 30 is in the form of a frame around the organic EL device 20 and bonds the periphery of the substrate 100 and the periphery of the sealing substrate 40 together. The getter member will be described in detail later.

The sealing substrate 40 and the TFT substrate 10 on which the organic EL device 20 is disposed are bonded together with the adhesive layer 30, thereby sealing the organic EL device 20 between these substrates 10 and 40. This prevents oxygen and water from entering the organic EL device 20.

As illustrated in FIG. 3, the TFT substrate 10 includes a transparent insulating substrate 11, such as a glass substrate, as a supporting substrate. As illustrated in FIG. 2, a plurality of electric wires 14 are disposed on a main surface 11a of the insulating substrate 11. The electric wires 14 include a plurality of gate lines in the horizontal (transverse) direction and a plurality of signal lines in the vertical (longitudinal) direction crossing the gate lines. The gate lines are coupled to a gate line driving circuit (not shown) for driving the gate lines. The signal lines are coupled to a signal line driving circuit (not shown) for driving the signal lines.

The organic EL display apparatus 1 is an active-matrix display apparatus for RGB full-color display and includes a red (R), green (G), or blue (B) sub-pixel (dot) 2R, 2G, or 2B in each region divided by the electric wires 14. The sub-pixels 2R, 2G, and 2B are arranged in a matrix. The sub-pixels 2R, 2G, and 2B include the organic EL device 20 of their respective colors.

The red, green, and blue sub-pixels 2R, 2G, and 2B emit red light, green light, and blue light, respectively. Three sub-pixels 2R, 2G, and 2B constitute one pixel 2.

The sub-pixels 2R, 2G, and 2B include opening portions 15R, 15G, and 15B, respectively. The opening portions 15R, 15G, and 15B are covered with red, green, and blue light-emitting layers 23R, 23G, and 23B, respectively. The light-emitting layers 23R, 23G, and 23B are formed in a striped pattern in the vertical (longitudinal) direction. The pattern of each of the light-emitting layers 23R, 23G, and 23B is formed by vapor deposition. The opening portions 15R, 15G, and 15B will be described later.

Each of the sub-pixels 2R, 2G, and 2B includes the TFT 12 coupled to a first electrode 21 of the organic EL device 20. The luminescence intensity of each of the sub-pixels 2R, 2G, and 2B is determined by scanning and selection with the electric wires 14 and the TFTs 12. Thus, the organic EL display apparatus 1 displays images by using the TFTs 12 to selectively emit light with desired luminance from the organic EL device 20 of each color.

The structures of the TFT substrate 10 and the organic EL device 20 will be described in detail below. First, the TFT substrate 10 will be described below.

As illustrated in FIG. 3, the TFT substrate 10 includes the TFTs 12 (switching devices) and the electric wires 14 on the main surface 11a of the insulating substrate 11, an interlayer film (interlayer insulating film, planarizing film) 13 covering the TFTs 12 and the electric wires 14, and an edge cover 15, which is an insulating layer on the interlayer film 13.

The TFT 12 is disposed in each of the sub-pixels 2R, 2G, and 2B. The TFT 12 may have a general structure, and each layer of the TFT 12 is not shown or described here. The TFT 12 may include a silicon nitride film.

The interlayer film 13 is disposed on the main surface 11a of the insulating substrate 11 and over the entire insulating substrate 11. The first electrode 21 of the organic EL device 20 is disposed on the interlayer film 13. The interlayer film 13 has a contact hole 13a through which the first electrode 21 is electrically connected to the TFT 12. Thus, the TFT 12 is electrically connected to the organic EL device 20 through the contact hole 13a.

The edge cover 15 is formed to prevent a short circuit between the first electrode 21 and a second electrode 26 of the organic EL device 20 caused by a decrease in the thickness of the organic EL layer or electric field concentration at an end of the first electrode 21. Thus, the edge cover 15 is formed to partly cover an end of the first electrode 21.

The edge cover 15 has the opening portions 15R, 15G, and 15B. In the opening portions 15R, 15G, and 15B, the sub-pixels 2R, 2G, and 2B emit light. In other words, the sub-pixels 2R, 2G, and 2B are separated by the insulating edge cover 15. The edge cover 15 also functions as a device isolation film.

Next, the organic EL device 20 will be described below.

The organic EL device 20 is a light-emitting device that can emit high-intensity light by direct-current drive and includes the first electrode 21, the organic EL layer, and the second electrode 26 stacked in this order.

The first electrode 21 is a layer that functions to inject (supply) positive holes into the organic EL layer. As described above, the first electrode 21 is coupled to the TFT 12 through the contact hole 13a.

As illustrated in FIG. 3, a hole-injection and hole-transport layer 22, a light-emitting layer 23R, 23G, or 23B, an electron-transport layer 24, and an electron-injection layer 25 are stacked in this order on the first electrode 21 between the first electrode 21 and the second electrode 26, thus forming the organic EL layer.

This stacking sequence in the organic EL layer is valid in the case where the first electrode 21 is a positive electrode, and the second electrode 26 is a negative electrode, and the stacking sequence is reversed in the case where the first electrode 21 is a negative electrode, and the second electrode 26 is a positive electrode.

The hole-injection layer functions to increase the efficiency of hole injection into the light-emitting layers 23R, 23G, and 23B. The hole-transport layer functions to increase the efficiency of hole transport to the light-emitting layers 23R, 23G, and 23B. The hole-injection and hole-transport layer 22 is uniformly formed over the entire light-emitting region of the substrate 100 so as to cover the first electrodes 21 and the edge covers 15.

In the present embodiment, as described above, the hole-injection layer and the hole-transport layer are integrated into the hole-injection and hole-transport layer 22. However, the present embodiment is not limited to this. The hole-injection layer and the hole-transport layer may be separately formed.

The light-emitting layers 23R, 23G, and 23B are formed on the hole-injection and hole-transport layer 22 so as to cover the opening portions 15R, 15G, and 15B of the edge covers 15 in the sub-pixels 2R, 2G, and 2B, respectively.

The light-emitting layers 23R, 23G, and 23B function to recombine holes (positive holes) injected from the first electrode 21 and electrons injected from the second electrode 26 and thereby emit light. The light-emitting layers 23R, 23G, and 23B are formed of a material with high luminous efficiency, such as a low-molecular-weight fluorescent dye or a metal complex.

The electron-transport layer 24 functions to increase the efficiency of electron transport from the second electrode 26 to the light-emitting layers 23R, 23G, and 23B. The electron-injection layer 25 functions to increase the efficiency of electron injection from the second electrode 26 into the light-emitting layers 23R, 23G, and 23B.

The electron-transport layer 24 is uniformly formed over the entire light-emitting region of the substrate 100 so as to cover the light-emitting layers 23R, 23G, and 23B and the hole-injection and hole-transport layer 22. The electron-injection layer 25 is uniformly formed over the entire light-emitting region of the substrate 100 so as to cover the electron-transport layer 24.

The electron-transport layer 24 and the electron-injection layer 25 may be separately formed or may be integrated, as described above. More specifically, the organic EL display apparatus 1 may include an electron-transport and electron-injection layer instead of the electron-transport layer 24 and the electron-injection layer 25.

The second electrode 26 is a layer that functions to inject electrons into the organic EL layer. The second electrode 26 is uniformly formed over the entire light-emitting region of the substrate 100 so as to cover the electron-injection layer 25.

The organic layers other than the light-emitting layers 23R, 23G, and 23B are not essential for the organic EL layer and may be appropriately formed depending on the desired characteristics of the organic EL device 20. The organic EL layer may further include a carrier-blocking layer, if necessary. For example, a hole-blocking layer may be disposed as a carrier-blocking layer between the light-emitting layers 23R, 23G, and 23B and the electron-transport layer 24. The hole-blocking layer can prevent positive holes from reaching the electron-transport layer 24 and improve luminous efficiency.

The organic EL device 20 may have the following layer structures (1) to (8), for example.

(1) First electrode/light-emitting layer/second electrode

(2) First electrode/hole-transport layer/light-emitting layer/electron-transport layer/second electrode

(3) First electrode/hole-transport layer/light-emitting layer/hole-blocking layer/electron-transport layer/second electrode

(4) First electrode/hole-transport layer/light-emitting layer/hole-blocking layer/electron-transport layer/electron-injection layer/second electrode

(5) First electrode/hole-injection layer/hole-transport layer/light-emitting layer/electron-transport layer/electron-injection layer/second electrode

(6) First electrode/hole-injection layer/hole-transport layer/light-emitting layer/hole-blocking layer/electron-transport layer/second electrode

(7) First electrode/hole-injection layer/hole-transport layer/light-emitting layer/hole-blocking layer/electron-transport layer/electron-injection layer/second electrode

(8) First electrode/hole-injection layer/hole-transport layer/electron-blocking layer (carrier-blocking layer)/light-emitting layer/hole-blocking layer/electron-transport layer/electron-injection layer/second electrode

As described above, the hole-injection layer and the hole-transport layer may be integrated. The electron-transport layer and the electron-injection layer may also be integrated.

The structure of the organic EL device 20 is not limited to the layer structures (1) to (8) and may be a desired layer structure depending on the desired characteristics of the organic EL device 20.

Next, a method for manufacturing the organic EL display apparatus 1 will be described below.

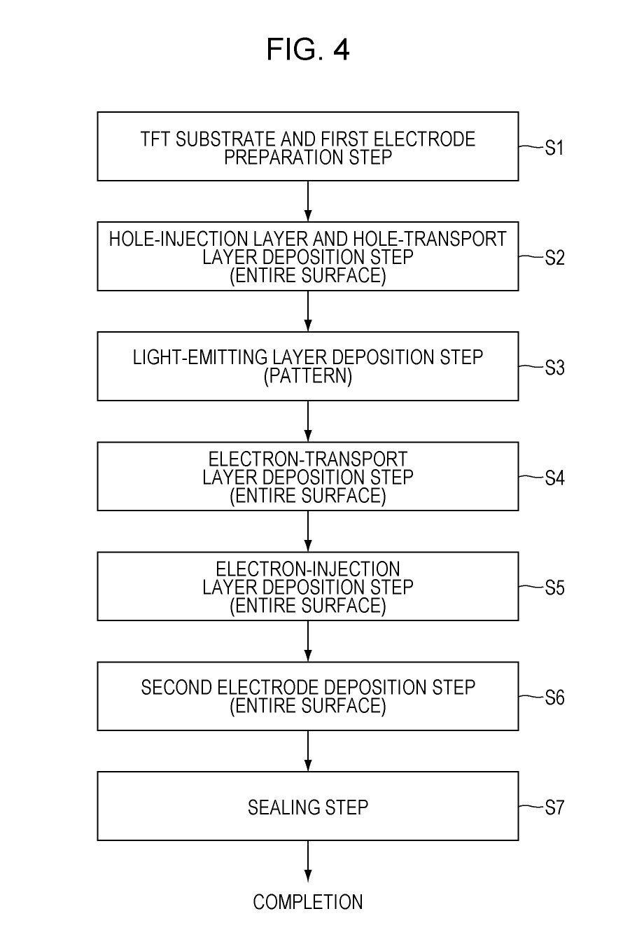

FIG. 4 is a flow chart illustrating a process for manufacturing the organic EL display apparatus according to the first embodiment.

As illustrated in FIG. 4, a method for manufacturing the organic EL display apparatus according to the present embodiment includes a TFT substrate and first electrode preparation step S1, a hole-injection layer and hole-transport layer deposition step S2, a light-emitting layer deposition step S3, an electron-transport layer deposition step S4, an electron-injection layer deposition step S5, a second electrode deposition step S6, and a sealing step S7, for example.

Referring to the flow chart of FIG. 4, a step of manufacturing each of the constituents illustrated in FIGS. 1 to 3 will be described below. The dimensions, materials, and shapes of the constituents described in the present embodiment are only examples and do not limit the scope of the present invention.

As described above, the stacking sequence in the organic EL layer described in the present embodiment is valid in the case where the first electrode 21 is a positive electrode, and the second electrode 26 is a negative electrode, and is reversed in the case where the first electrode 21 is a negative electrode, and the second electrode 26 is a positive electrode. Likewise, the materials of the first electrode 21 and the second electrode 26 are also exchanged.

First, as illustrated in FIG. 3, a photosensitive resin is applied by a general method to the insulating substrate 11 on which the TFTs 12 and the electric wires 14 are formed, and is patterned by a photolithography technique to form the interlayer film 13 on the insulating substrate 11.

The insulating substrate 11 may be a rectangular glass or plastic substrate having a thickness in the range of 0.7 to 1.1 mm, a length in the range of 400 to 500 mm in the Y-axis direction (vertical length), and a length in the range of 300 to 400 mm in the X-axis direction (horizontal length).

The material of the interlayer film 13 may be an organic resin, such as an acrylic resin or a polyimide resin. Examples of the acrylic resin include the Optmer series manufactured by JSR Corporation. Examples of the polyimide resin include the Photoneece series manufactured by Toray Industries, Inc. Polyimide resins are generally opaque and colored. Thus, when an organic EL display apparatus of a bottom emission type is manufactured as the organic EL display apparatus 1, as illustrated in FIG. 3, the interlayer film 13 is preferably a transparent resin, such as an acrylic resin. The interlayer film 13 may include a silicon nitride film and an organic resin film disposed on the silicon nitride film.

The interlayer film 13 may have any thickness, provided that the steps at the TFTs 12 are eliminated and that the interlayer film 13 has a flat surface. For example, the interlayer film 13 has a thickness of approximately 2 μm.

The contact hole 13a for electrically connecting the first electrode 21 to the TFT 12 is then formed in the interlayer film 13.

An electrically conductive film, for example, an indium tin oxide (ITO) film, having a thickness of 100 nm is then formed by a sputtering method.

A photoresist is then applied to the ITO film and is patterned by a photolithography technique. The ITO film is then etched with an iron (III) chloride etchant. The photoresist is then removed with a resist stripping liquid, and the substrate is washed. Thus, a matrix of the first electrodes 21 is formed on the interlayer film 13.

The positive electrode material (the material of the first electrodes 21) may be a transparent electrically conductive material, such as ITO, indium zinc oxide (IZO), or gallium-doped zinc oxide (GZO), or a metallic material, such as gold (Au), nickel (Ni), or platinum (Pt).

A method for forming the electrically conductive film other than the sputtering method may be a vacuum deposition method, a chemical vapor deposition (CVD) method, a plasma CVD method, or a printing method.

The first electrode 21 may have any thickness, for example, 100 nm, as described above.

The edge covers 15, for example, having a thickness of approximately 1 μm are then formed by the same method as for the interlayer film 13. The material of the edge covers 15 may be the same insulating material as for the interlayer film 13, for example, an organic resin.

Through these steps, the TFT substrate 10 and the first electrodes 21 are formed (S1).

The TFT substrate 10 subjected to these steps is then subjected to vacuum baking for dehydration and oxygen plasma treatment for surface cleaning of the first electrodes 21.

A hole-injection layer and a hole-transport layer (the hole-injection and hole-transport layer 22 in the present embodiment) are then formed by vacuum deposition with a vacuum deposition apparatus on the TFT substrate 10 over the entire light-emitting region of the substrate 100 (S2).

More specifically, a mask having an opening corresponding to the entire light-emitting region is aligned with and bonded to the substrate 100. While both the substrate 100 and the mask are rotated, depositing particles scattering from an evaporation source are uniformly deposited over the entire light-emitting region through the opening portion of the mask.

Vapor deposition over the entire light-emitting region means continuous vapor deposition across adjacent sub-pixels of different colors.

Examples of the materials of the hole-injection layer and the hole-transport layer include benzine, styrylamine, triphenylamine, porphyrin, triazole, imidazole, oxadiazole, polyarylalkane, phenylenediamine, arylamine, oxazole, anthracene, fluorenone, hydrazone, stilbene, triphenylene, azatriphenylene, and derivatives thereof; polysilane compounds; vinylcarbazole compounds; and monomers, oligomers, and polymers of heterocyclic conjugated systems, such as thiophene compounds and aniline compounds.

The hole-injection layer and the hole-transport layer may be integrated or separately formed, as described above. Each of the hole-injection layer and the hole-transport layer has a thickness in the range of 10 to 100 nm, for example.

When the hole-injection and hole-transport layer 22 is formed as the hole-injection layer and the hole-transport layer, the material of the hole-injection and hole-transport layer 22 may be 4,4′-bis[N-(1-naphthyl)-N-phenylamino]biphenyl (α-NPD). The hole-injection and hole-transport layer 22 has a thickness of 30 nm, for example.

The light-emitting layers 23R, 23G, and 23B in the sub-pixels 2R, 2G, and 2B are then separately formed (patterned) on the hole-injection and hole-transport layer 22 so as to cover the opening portions 15R, 15G, and 15B of the edge covers 15 (S3).

As described above, the light-emitting layers 23R, 23G, and 23B are formed of a material with high luminous efficiency, such as a low-molecular-weight fluorescent dye or a metal complex.

Examples of the material of the light-emitting layers 23R, 23G, and 23B include anthracene, naphthalene, indene, phenanthrene, pyrene, naphthacene, triphenylene, anthracene, perylene, picene, fluoranthene, acephenanthrylene, pentaphene, pentacene, coronene, butadiene, coumarin, acridine, stilbene, and derivatives thereof; tris(8-quinolinolato)aluminum complex; bis(benzoquinolinolato)beryllium complex; tri(dibenzoylmethyl)phenanthroline europium complex; and ditoluylvinylbiphenyl.

Each of the light-emitting layers 23R, 23G, and 23B has a thickness in the range of 10 to 100 nm, for example.

A method for forming the pattern of each of the light-emitting layers 23R, 23G, and 23B will be described in detail later.

In the same manner as the hole-injection layer and hole-transport layer deposition step S2, the electron-transport layer 24 is deposited over the entire light-emitting region of the substrate 100 so as to cover the hole-injection and hole-transport layer 22 and the light-emitting layers 23R, 23G, and 23B (S4).

In the same manner as the hole-injection layer and hole-transport layer deposition step S2, the electron-injection layer 25 is then deposited over the entire light-emitting region of the substrate 100 so as to cover the electron-transport layer 24 (S5).

Examples of the materials of the electron-transport layer 24 and the electron-injection layer 25 include quinoline, perylene, phenanthroline, bisstyryl, pyrazine, triazole, oxazole, oxadiazole, fluorenone, and derivatives and metal complexes thereof; and lithium fluoride (LiF).

More specifically, the materials of the electron-transport layer 24 and the electron-injection layer 25 include tris(8-hydroxyquinoline) aluminum (Alq₃), anthracene, naphthalene, phenanthrene, pyrene, anthracene, perylene, butadiene, coumarin, acridine, stilbene, 1,10-phenanthroline, and derivatives and metal complexes thereof; and LiF.

As described above, the electron-transport layer 24 and the electron-injection layer 25 may be integrated or separately formed. Each of the electron-transport layer 24 and the electron-injection layer 25 may have a thickness in the range of 1 to 100 nm, preferably 10 to 100 nm. The electron-transport layer 24 and the electron-injection layer 25 have a total thickness in the range of 20 to 200 nm, for example.

Typically, the material of the electron-transport layer 24 is Alq₃, and the material of the electron-injection layer 25 is LiF. The electron-transport layer 24 may have a thickness of 30 nm, and the electron-injection layer 25 may have a thickness of 1 nm.

In the same manner as the hole-injection layer and hole-transport layer deposition step S2, the second electrode 26 is then deposited over the entire light-emitting region of the substrate 100 so as to cover the electron-injection layer 25 (S6). Thus, the organic EL device 20 including the organic EL layer, the first electrode 21, and the second electrode 26 is formed on the TFT substrate 10.

The negative electrode material (the material of the second electrode 26) is preferably a metal with a low work function. Examples of such a material include magnesium alloys (such as MgAg), aluminum alloys (such as AlLi, AlCa, and AlMg), and metallic calcium. The second electrode 26 has a thickness in the range of 50 to 100 nm, for example.

Typically, the second electrode 26 is formed of an aluminum thin film having a thickness of 50 nm.

As illustrated in FIG. 1, the substrate 100 including the organic EL device 20 and the sealing substrate 40 are then bonded together with the adhesive layer 30 to seal the organic EL device 20.

The material of the adhesive layer 30 may be a sealing resin or frit glass. The sealing substrate 40 may be an insulating substrate, such as a glass substrate or a plastic substrate, having a thickness in the range of 0.4 to 1.1 mm. The sealing substrate 40 may be an engraved glass.

The vertical length and horizontal length of the sealing substrate 40 may be adjusted for the size of the organic EL display apparatus 1. An insulating substrate having almost the same size as the insulating substrate 11 of the TFT substrate 10 may be used, and may be cut into the size of the organic EL display apparatus 1 after the organic EL device 20 is sealed.

A method for sealing the organic EL device 20 is not limited to the method described above and may be any other sealing method. Another sealing method may be a method of filling a space between the TFT substrate 10 and the sealing substrate 40 with a resin.

In order to prevent oxygen and water from entering the organic EL device 20, a protective film (not shown) may be disposed on the second electrode 26 so as to cover the second electrode 26.

The protective film may be formed of an insulating or electrically conductive material. Such a material may be silicon nitride or silicon oxide. The protective film has a thickness in the range of 100 to 1000 nm, for example.

Through these steps, the organic EL display apparatus 1 is completed.

In the organic EL display apparatus 1, when the TFTs 12 are turned on in response to a signal from the electric wires 14, holes (positive holes) are injected from the first electrode 21 into the organic EL layer. Concurrently, electrons are injected from the second electrode 26 into the organic EL layer and recombine with positive holes in the light-emitting layers 23R, 23G, and 23B. Recombination energy of positive holes and electrons excites a light-emitting material. Upon transition from the excited state to the ground state, light is emitted. The luminance of each of the sub-pixels 2R, 2G, and 2B in each pixel 2 can be independently adjusted to control the electroluminescence of the sub-pixels 2R, 2G, and 2B, thereby displaying desired images in the light-emitting region composed of the pixels 2.

The light-emitting layer deposition step S3 and an apparatus for manufacturing an organic EL display apparatus according to the present embodiment will be described in detail below. The light-emitting layer deposition step S3 is performed with the apparatus for manufacturing an organic EL display apparatus according to the present embodiment.

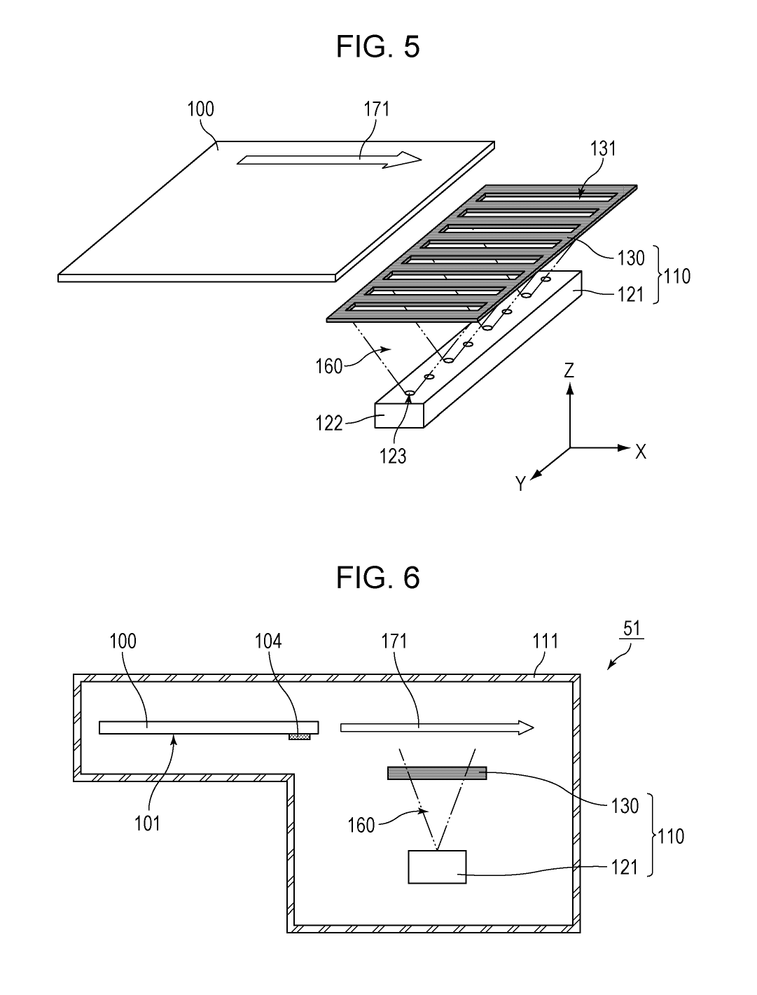

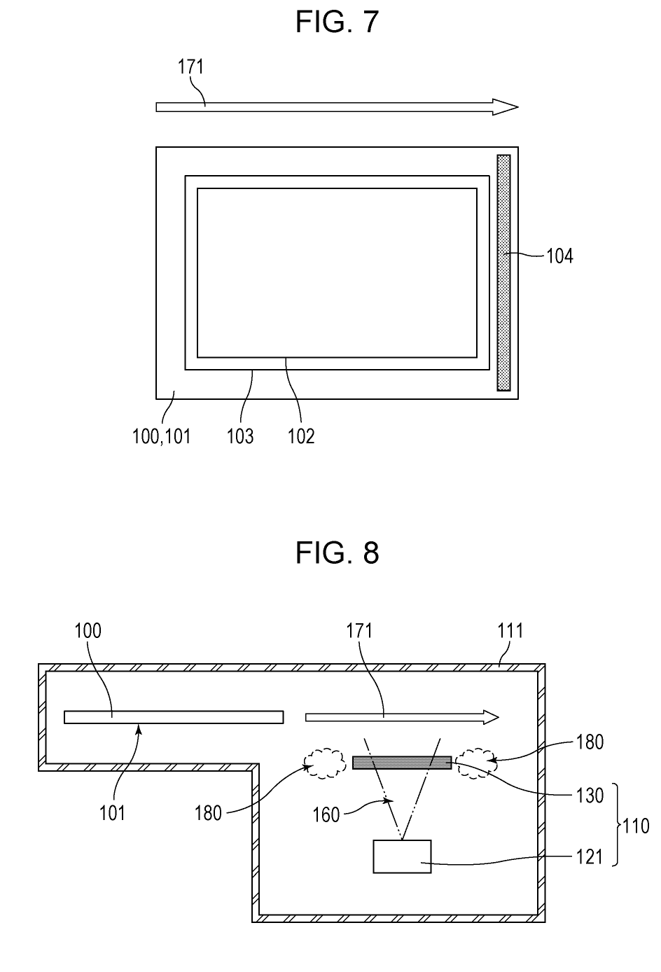

FIG. 5 is a schematic view illustrating the light-emitting layer deposition step in the method for manufacturing the organic EL display apparatus according to the first embodiment and illustrating the apparatus for manufacturing the organic EL display apparatus according to the first embodiment and is a perspective view of the organic EL display substrate according to the first embodiment and the apparatus for manufacturing the organic EL display apparatus according to the first embodiment. FIG. 6 is a schematic view illustrating the light-emitting layer deposition step in the method for manufacturing the organic EL display apparatus according to the first embodiment and illustrating the apparatus for manufacturing the organic EL display apparatus according to the first embodiment and is a cross-sectional view of the organic EL display substrate according to the first embodiment and the apparatus for manufacturing the organic EL display apparatus according to the first embodiment. FIG. 7 is a schematic plan view of the organic EL display substrate according to the first embodiment.

As illustrated in FIGS. 5 and 6, an apparatus 51 for manufacturing an organic EL display apparatus according to the present embodiment is a vacuum deposition apparatus, particularly a scanning deposition apparatus, and includes a vapor deposition unit 110, a vapor deposition chamber (vacuum chamber) 111, a vacuum pump (not shown), a substrate holder (not shown), and a conveying mechanism (not shown). The vapor deposition unit 110 includes an evaporation source 121, a mask 130 disposed above the evaporation source 121, and a frame (not shown). The apparatus 51 for manufacturing an organic EL display apparatus according to the present embodiment is hereinafter also referred to as a scanning deposition apparatus 51.

The vapor deposition chamber 111 is a container that forms a space for vacuum deposition and includes the substrate holder, the conveying mechanism, and the vapor deposition unit 110. The vapor deposition chamber 111 is coupled to a vacuum pump. For vapor deposition, the vapor deposition chamber 111 is evacuated (depressurized) with the vacuum pump and is maintained at low pressure.

The substrate holder is a member for holding a substrate for vacuum deposition (film formation), that is, the organic EL display substrate 100. The substrate holder holds the substrate 100 such that a vapor deposition surface 101 of the substrate 100 faces the mask 130. The substrate holder is preferably an electrostatic chuck or a substrate tray.

Before the light-emitting layer deposition step S3, the TFT 12, the electric wires 14, the interlayer film 13, the first electrode 21, the edge covers 15, and the hole-injection and hole-transport layer 22 are formed on the insulating substrate 11 of the substrate 100, as described above.

As illustrated in FIG. 7, the substrate 100 includes a rectangular light-emitting region 102 including the pixels 2 and a rectangular vapor deposition region 103.

As described above, each of the pixels 2 is composed of the three sub-pixels 2R, 2G, and 2B. Each of the sub-pixels 2R, 2G, and 2B includes the organic EL device 20 including the organic EL layer. Consequently, desired images can be displayed with the pixels 2 in the light-emitting region 102. Thus, the light-emitting region 102 functions as an image display area.

The vapor deposition region 103 is a region in which vacuum deposition materials (the materials of the light-emitting layers 23R, 23G, and 23B) are deposited in the light-emitting layer deposition step S3. The vapor deposition region 103 covers at least the light-emitting region 102 so that the materials spread over the sub-pixels 2R, 2G, and 2B.

The substrate 100, the light-emitting region 102, and the vapor deposition region 103 may have any planar shape and are, in general, rectangular. Each of the substrate 100, the light-emitting region 102, and the vapor deposition region 103 generally has a pair of long sides and a pair of short sides.

As illustrated in FIG. 7, the substrate 100 includes a getter member 104. The getter member 104 is a member that adsorbs contamination in the vapor deposition chamber 111 and is not a member that is electrically connected to an electrode, an electric wire, a terminal, or the like. Thus, the getter member 104 is electrically insulated. The getter member 104 is disposed in part of the area around the light-emitting region 102 and the vapor deposition region 103 on the main surface 11a of the insulating substrate 11 and extends along at least one side of each of the regions 102 and 103. As illustrated in FIG. 7, the getter member 104 may be formed in a band shape in a plan view or may be disposed along one of a pair of short sides of each of the regions 102 and 103. The getter member 104 is separated from the light-emitting region 102 and the vapor deposition region 103 and is formed in a pattern isolated or disconnected from the pattern of a constituent (for example, the first electrode 21 or the organic EL layer) in the light-emitting region 102.

The conveying mechanism is coupled to the substrate holder and can move the substrate 100 held by the substrate holder in the direction perpendicular to the direction normal to the substrate 100 (in a conveying direction 171) at a constant speed. The vapor deposition unit 110 is fixed to the vapor deposition chamber 111 and is stationary. Thus, the conveying mechanism can move the substrate 100 in the conveying direction 171 relative to the vapor deposition unit 110. The conveying mechanism may include a linear guide, a ball screw, a motor coupled to the ball screw, and a motor drive control unit coupled to the motor. The motor drive control unit drives the motor to move the substrate holder and the substrate 100 in an integrated manner.

The conveying mechanism can move the substrate 100 relative to the vapor deposition unit 110. Thus, the conveying mechanism may be coupled to the substrate holder and the vapor deposition unit and may move both the substrate 100 and the vapor deposition unit 110.

The evaporation source 121 heats and vaporizes, that is, evaporates or sublimates a vacuum deposition material (preferably an organic material) and releases the vaporized material into the vapor deposition chamber 111. The evaporation source 121 is disposed in a lower portion of the vapor deposition chamber 111. More specifically, the evaporation source 121 includes a heat-resistant container (not shown) for a material, for example, a crucible, a heating apparatus (not shown) for heating the material in the container, for example, a heater and a heating power supply, and a diffusion unit 122, which forms a space through which the vaporized material diffuses. The diffusion unit 122 includes opening portions (ejection port) 123 at the top thereof. A material in the container is heated and vaporized by the heating apparatus. The evaporation source 121 releases the gaseous material (hereinafter also referred to as depositing particles) upward from the opening portions 123. Consequently, a vapor deposition flow 160, which is a flow of depositing particles, from the opening portions 123 spreads isotropically from the opening portions 123.

The mask 130 has openings 131 for use in patterning. Thus, part of depositing particles reaching the mask 130 can pass through the openings 131 and can be deposited onto the substrate 100 in a pattern corresponding to the openings 131.

The evaporation source 121 may be of any type, for example, a point evaporation source (point source), a linear evaporation source (linear source), or a plane evaporation source. A method for heating the evaporation source 121 is not particularly limited and may be a resistance heating method, an electron beam method, a laser deposition method, a high-frequency induction heating method, or an arc method.

The frame is a frame-shaped reinforcing member and is welded to the mask 130. Thus, the frame suppresses the deformation of the mask 130.

In the light-emitting layer deposition step S3, first, the vapor deposition chamber 111 is evacuated to a low-pressure state. The material is heated to produce the vapor deposition flow 160. The substrate 100 is conveyed into the vapor deposition chamber 111 through an entrance (not shown) and is held by the substrate holder. The substrate 100 is placed such that the getter member 104 faces the evaporation source 121 before the light-emitting region 102 faces the evaporation source 121, that is, such that the getter member 104 is located in the traveling direction (in front) of the light-emitting region 102. As illustrated in FIG. 6, the conveying mechanism conveys (moves, scans) the substrate 100 in the conveying direction 171 above the mask 130. Consequently, depositing particles passing through the openings 131 adhere one after another to the substrate 100, which is moving relative to the vapor deposition unit 110. Thus, a deposited film, that is, the light-emitting layer 23R, 23G, or 23B is formed in a pattern corresponding to the openings 131.

With the scanning deposition apparatus 51, the mask 130 can be smaller than the substrate 100 and can therefore be easily manufactured. Thus, deformation of the mask 130 due to the weight of the mask 130 itself can be reduced.

In the scanning deposition apparatus 51, however, at least one of the substrate 100 and the vapor deposition unit 110 is conveyed, and therefore the number of driving parts is greater than known vacuum deposition apparatuses. Grease applied to these driving parts is scattered around the vapor deposition chamber 111 during evacuation, heating, and conveyance, thus causing contamination.

FIG. 8 is a schematic view illustrating a light-emitting layer deposition step in a method for manufacturing an organic EL display apparatus according to Comparative Embodiment 1 and is a cross-sectional view of an organic EL display substrate and a scanning deposition apparatus.

Comparative Embodiment 1 is substantially the same as the first embodiment except that the organic EL display substrate includes no getter member. As illustrated in FIG. 8, in Comparative Embodiment 1, the organic EL display substrate 100 is conveyed through contamination 180 in the vapor deposition chamber 111. Thus, the entire surface of the substrate 100 is contaminated, resulting in low luminance.

In contrast, in the present embodiment, as illustrated in FIG. 7, the substrate 100 includes the getter member 104 that can adsorb contamination, and the getter member 104 is disposed in at least part of the area around the light-emitting region 102.

The substrate 100 including the getter member 104 can be introduced into the vapor deposition chamber 111 of the scanning deposition apparatus 51 together with the getter member 104. Because the getter member 104 is disposed in at least part of the area around the light-emitting region 102, the substrate 100 can be conveyed such that the getter member 104 faces the vapor deposition unit 110 including the evaporation source 121 before the light-emitting region 102 faces the vapor deposition unit 110. Thus, in the present embodiment, while the substrate 100 is conveyed, the getter member 104 can precede the light-emitting region 102. The getter member 104 can adsorb contamination while moving through the contamination region, and thereafter the light-emitting region 102 and the vapor deposition region 103 can move through the region in which the getter member 104 has adsorbed contamination. Thus, the substrate 100 can be conveyed and subjected to vacuum deposition treatment while the getter member 104 removes contamination. This can reduce contamination of the light-emitting region 102 and the vapor deposition region 103 and consequently suppress a decrease in luminance due to contamination.

The getter member 104 is disposed in at least part of the area around the light-emitting region 102, that is, outside the light-emitting region 102. This can prevent contamination on the getter member 104 from adversely affecting the characteristics of the organic EL device 20.

The getter member 104, together with the substrate 100, is disposed in the vapor deposition chamber 111. Thus, unlike the case where the technical idea described in Patent Literature 1 is applied to the vacuum deposition method as described above, contamination in the vapor deposition chamber 111 can be effectively prevented from adhering to the light-emitting region 102 and the vapor deposition region 103.

Because the getter member 104 is disposed in the vapor deposition chamber 111, unlike the case where the technical idea described in Patent Literature 1 is applied to the vacuum deposition method as described above, no large exhaust system is required.

Furthermore, because the substrate 100 rather than the scanning deposition apparatus 51 includes the getter member 104, when a plurality of organic EL display substrates are subjected to vapor deposition, each of the substrates can include the getter member. Thus, even if the getter member deteriorates, periodical maintenance, such as application of another getter member, or removal of the getter member is not necessary. Thus, the capacity utilization of the scanning deposition apparatus 51 is not reduced.

A method for manufacturing an organic EL display apparatus according to the present embodiment includes a vapor deposition step of depositing a material released from the evaporation source 121 onto the organic EL display substrate 100 according to the present embodiment while conveying at least one of the substrate 100 and the evaporation source 121 that vaporizes and releases the material to move the substrate 100 relative to the evaporation source 121. In the vapor deposition step, at least one of the substrate 100 and the evaporation source 121 is conveyed such that the getter member 104 faces the evaporation source 121 before the light-emitting region 102 faces the evaporation source 121. Thus, as described above, this can suppress a decrease in luminance due to contamination, can prevent contamination on the getter member 104 from adversely affecting the characteristics of the organic EL device 20, and can prevent a decrease in the capacity utilization of the scanning deposition apparatus 51.

Furthermore, the scanning deposition apparatus 51 according to the present embodiment is an apparatus for manufacturing an organic EL display apparatus that includes the evaporation source 121 that vaporizes and releases a material. The scanning deposition apparatus 51 deposits the material released from the evaporation source 121 onto the organic EL display substrate 100 according to the present embodiment while conveying at least one of the substrate 100 and the evaporation source 121 to move the substrate 100 relative to the evaporation source 121, and conveys at least one of the substrate 100 and the evaporation source 121 such that the getter member 104 faces the evaporation source 121 before the light-emitting region 102 faces the evaporation source 121. Thus, as described above, this can suppress a decrease in luminance due to contamination, can prevent contamination on the getter member 104 from adversely affecting the characteristics of the organic EL device 20, and can prevent a decrease in the capacity utilization of the scanning deposition apparatus 51.

The specific material of the getter member 104 may be any material that can adsorb contamination, that is, any material that characteristically adsorbs contamination, and preferably contains at least one material selected from the group consisting of aluminum (Al), copper (Cu), molybdenum (Mo), titanium (Ti), silicon (Si), a silicon nitride film material (that is, silicon nitride), organic resins, positive electrode materials, hole-injection layer materials, hole-transport layer materials, and light-emitting layer materials. This is because these materials characteristically adsorb contamination, can be used for the formation of the organic EL device 20 or the TFT 12, and can form the getter member 104 simultaneously with the organic EL device 20 or the TFT 12 without a film formation step for the getter member 104 alone. Examples of the organic resins include acrylic resins and polyimide resins, as described above.

Whether a material can adsorb contamination or not can be determined by placing the target material in the same environment as the vapor deposition chamber in the vapor deposition steps S3 to S6 and then directly or indirectly checking for contamination on the material surface. The direct checking method may be a method for analyzing a deposit on the material surface. The indirect checking method may be a method for directly checking for degradation of the characteristics of the material or a method of preparing an organic EL device from the material and checking for degradation of the characteristics of the organic EL device.

Typical organic EL display substrates generally include electric wires and terminals electrically connected to other members (for example, organic EL devices, TFTs, and electric wires) around the light-emitting region. These electric wires may be formed of aluminum, and these terminals may be formed of a positive electrode material, such as ITO. Thus, these electric wires and terminals can adsorb contamination. Also in typical organic EL display substrates, the vapor deposition region is generally larger than the light-emitting region, and therefore a hole-injection layer material, a hole-transport layer material, and/or a light-emitting layer material may be deposited around the light-emitting region. Thus, such a deposited portion around the light-emitting region can adsorb contamination. However, contamination on these electric wires and terminals as well as deposited portions around the light-emitting region is insufficiently removed. In contrast, the organic EL display substrate 100 according to the present embodiment includes the getter member 104 that can adsorb contamination, which can be utilized as a member exclusively used to adsorb contamination. Thus, contamination can be effectively removed.

In order to utilize the getter member 104 as a member exclusively used to adsorb contamination and effectively remove contamination, preferably, the getter member 104 is electrically insulated and separated from the light-emitting region 102.

The getter member 104 can be disposed on any part of the area around the light-emitting region 102 on the substrate 100. As illustrated in FIG. 7, the getter member 104 is preferably disposed across the full width of the light-emitting region 102, more preferably across the full width of the vapor deposition region 103. Thus, contamination can be effectively reduced throughout the light-emitting region 102 or the vapor deposition region 103. From the same perspective, the width of the region of the getter member 104 may be greater than the width of the light-emitting region 102 or the vapor deposition region 103 in the direction perpendicular to the conveying direction 171. In the case where the light-emitting region 102 is rectangular and has a pair of long sides and a pair of short sides, the getter member 104 may be disposed along at least the full length of a short side of the light-emitting region 102. In the case where the vapor deposition region 103 is rectangular and has a pair of long sides and a pair of short sides, the getter member 104 may be disposed along at least the full length of a short side of the vapor deposition region 103. The full length of a short side is from one end to the other end of the short side.

The distance (space) between the getter member 104 and the light-emitting region 102 is not particularly limited as long as no reflection occurs from the getter member in the organic EL display apparatus 1, and may be appropriately determined in consideration of design conditions, such as the size of the substrate 100 or the circuit layout.

The getter member 104 may have any planar shape and may be appropriately determined. As illustrated in FIG. 7, the getter member 104 may be linear, for example, in a linear band shape. As illustrated in FIG. 7, the getter member 104 may have a continuous pattern, that is, a pattern composed of one portion, or a discontinuous pattern, that is, a pattern composed of separate portions. In the latter case, the planar shape of each portion of the getter member 104 is not particularly limited and may be appropriately determined.

Contamination may be any substance (contaminant) that is found in a vapor deposition chamber (vacuum chamber) of the scanning deposition apparatus 51 and adversely affects the characteristics of the organic EL device. The specific substance of contamination is not particularly limited and may be a volatile component of a lubricant, such as grease. The source of contamination is not particularly limited and may be a lubricant, such as grease.

In the light-emitting layer deposition step S3, three types of light-emitting materials are used to perform the vapor deposition treatment three times, thereby successively forming the light-emitting layers 23R, 23G, and 23B of three colors. The order of the formation of the light-emitting layers 23R, 23G, and 23B is not particularly limited and may be appropriately determined. After all the light-emitting layers 23R, 23G, and 23B have been deposited, the substrate 100 is conveyed from the vapor deposition chamber 111 through an exit (not shown), thus completing the light-emitting layer deposition step S3.

A modified example of the first embodiment will be described below.

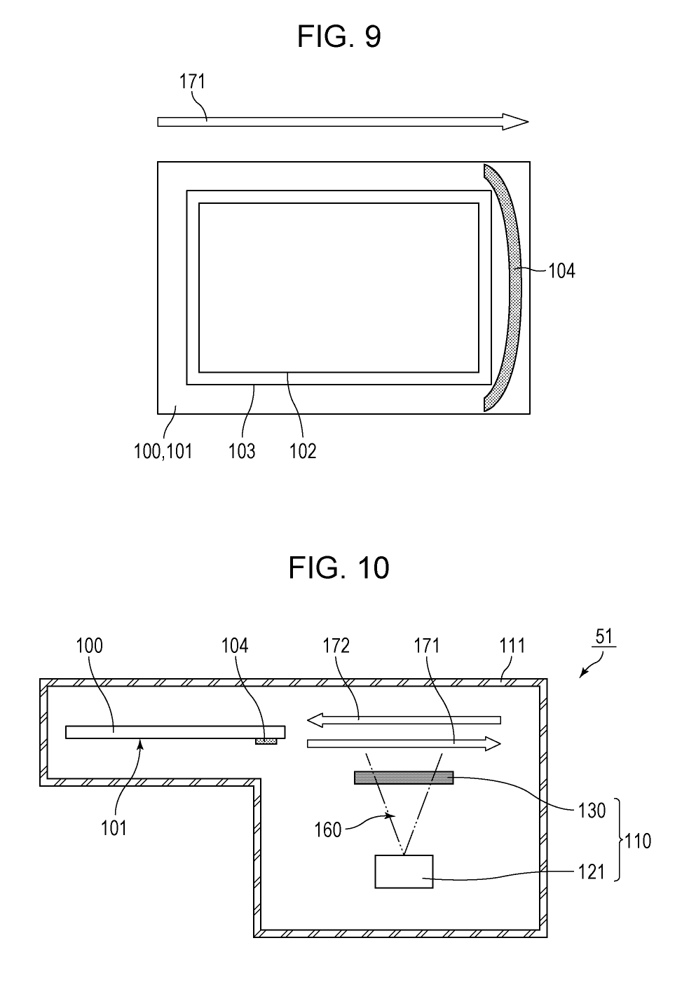

FIG. 9 is a schematic plan view of an organic EL display substrate according to a modified example of the first embodiment.

The planar shape of the getter member 104 is not limited to a linear shape as illustrated in FIG. 7 and may be a curved shape, for example, an arc or elliptical arc, as illustrated in FIG. 9.

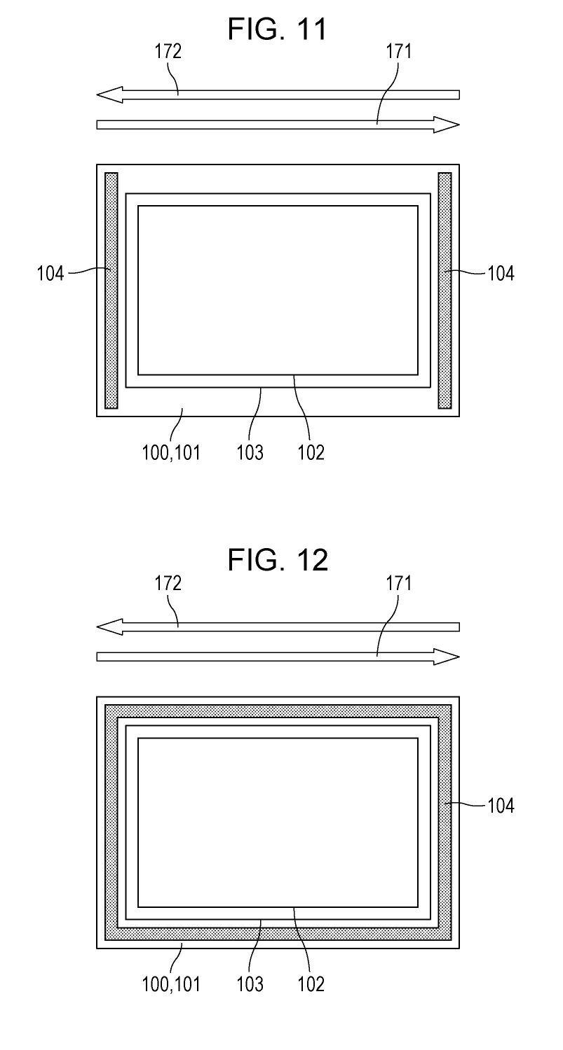

FIG. 10 is a schematic view illustrating a light-emitting layer deposition step in a method for manufacturing an organic EL display apparatus according to a modified example of the first embodiment and illustrating an apparatus for manufacturing an organic EL display apparatus according to the modified example of the first embodiment and is a cross-sectional view of the organic EL display substrate according to the modified example of the first embodiment and an apparatus for manufacturing an organic EL display apparatus according to the modified example of the first embodiment. FIG. 11 is a schematic plan view of an organic EL display substrate according to a modified example of the first embodiment. In the present modified example, as illustrated in FIG. 10, in the light-emitting layer deposition step S3, the scanning deposition apparatus 51 conveys the substrate 100 over the evaporation source 121 in the conveying direction 171 (forward) by a conveying mechanism and then conveys the substrate 100 over the evaporation source 121 again in the direction opposite to the conveying direction 171 (in a conveying direction 172) (backward) by the conveying mechanism without turning the substrate 100 around. Thus, vapor deposition treatment can be performed while the substrate 100 moves forward and backward over the evaporation source 121. Furthermore, the substrate 100 can be conveyed into and from the vapor deposition chamber 111 through the same part (exit and entrance).

In this case, however, when the getter member 104 is disposed in one place around the light-emitting region 102, as illustrated in FIG. 7, the substrate 100 may be contaminated while conveyed backward. Thus, in the present modified example, as illustrated in FIG. 11, the getter member 104 is disposed on both sides of each of the light-emitting region 102 and the vapor deposition region 103. The light-emitting region 102 and the vapor deposition region 103 are disposed between the two getter members 104. The getter members 104 are disposed along two opposite sides (for example, a pair of short sides) of the light-emitting region 102 and two opposite sides (for example, a pair of short sides) of the vapor deposition region 103.

The getter members 104 disposed in two opposite parts of the area around the light-emitting region 102 with the light-emitting region 102 interposed therebetween can adsorb contamination while the substrate 100 is conveyed not only forward but also backward. Thus, in the mode of vacuum deposition with the substrate 100 moving forward and backward over the evaporation source 121 and/or in the mode of the substrate 100 being conveyed into and from the vapor deposition chamber 111 through the same part, contamination of the light-emitting region 102 and the vapor deposition region 103 can be reduced.

From the same perspective as illustrated in FIG. 7, each of the getter members 104 is preferably disposed across the full width of the light-emitting region 102, more preferably across the full width of the vapor deposition region 103, as illustrated in FIG. 11. The width of each region of the getter members 104 may be greater than the width of the light-emitting region 102 or the vapor deposition region 103 in the direction perpendicular to the conveying direction 171 or 172 In the case where the light-emitting region 102 is rectangular and has a pair of long sides and a pair of short sides, each of the getter members 104 may be disposed along at least the full length of its adjacent short side of the pair of short sides of the light-emitting region 102. In the case where the vapor deposition region 103 is rectangular and has a pair of long sides and a pair of short sides, each of the getter members 104 may be disposed along at least the full length of its adjacent short side of the pair of short sides of the vapor deposition region 103.

FIG. 12 is a schematic plan view of an organic EL display substrate according to a modified example of the first embodiment.

As illustrated in FIG. 12, the getter member 104 may be a frame around the light-emitting region 102 and the vapor deposition region 103.

The getter member 104 disposed in the entire area around the light-emitting region 102 can have the same effects as the modified examples illustrated in FIGS. 10 and 11. The getter member 104 can also reduce contamination in the direction perpendicular to the conveying directions 171 and 172. This can more effectively reduce contamination of the light-emitting region 102 and the vapor deposition region 103 and consequently more effectively suppress a decrease in luminance due to contamination.

The characteristic vapor deposition step in the present embodiment, that is, the vapor deposition step involving the use of the substrate 100 including the getter member 104 may be applied to a vapor deposition step other than the light-emitting layer deposition step S3, for example, the electron-transport layer deposition step S4. Likewise, the scanning deposition apparatus 51 according to the present embodiment may be used in a vapor deposition step other than the light-emitting layer deposition step S3, for example, the electron-transport layer deposition step S4. This can reduce contamination on the substrate 100 also in a vapor deposition step for an organic EL layer other than the light-emitting layer or a second electrode and can therefore more effectively suppress a decrease in luminance due to contamination. Furthermore, an organic EL layer other than the light-emitting layer can be formed in the sub-pixel of each color.

### Second Embodiment

In the present embodiment, the distinct features of the present embodiment are mainly described, and the contents overlapping those of the first embodiment are omitted. Components having the same or similar functions in the present embodiment and the first embodiment are denoted by the same reference numerals and are not described in the present embodiment. The present embodiment is substantially the same as the first embodiment except for the points described below.

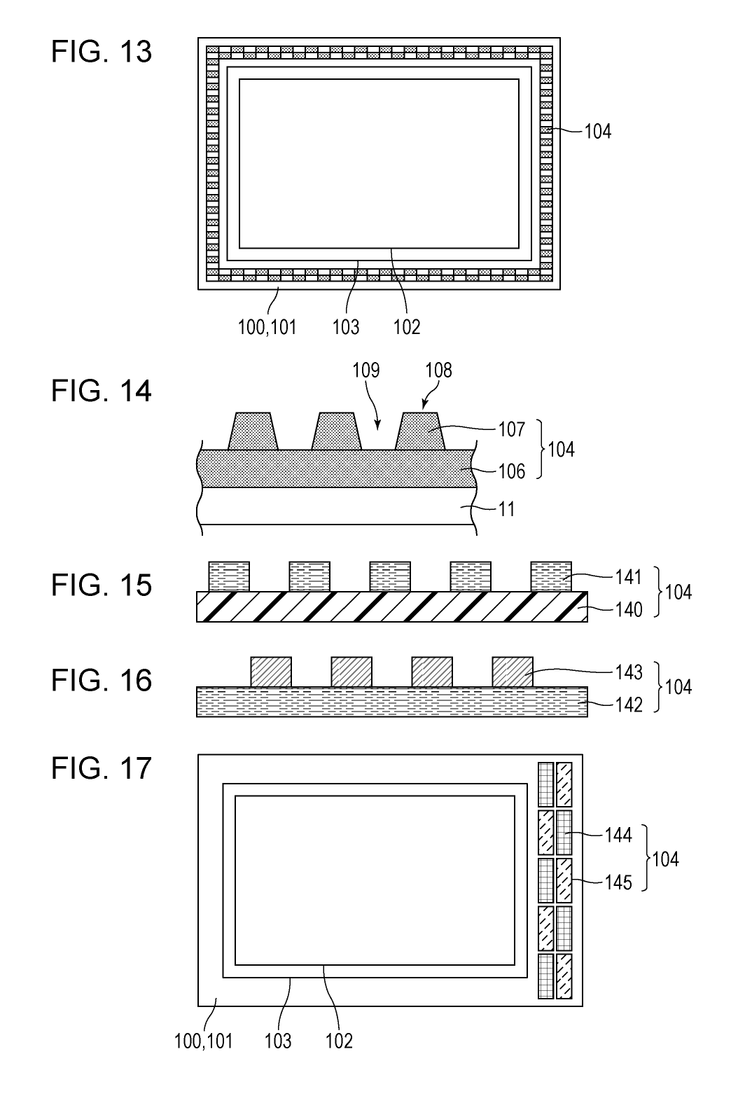

FIG. 13 is a schematic plan view of an organic EL display substrate according to a second embodiment. FIG. 14 is a schematic cross-sectional view of the organic EL display substrate according to the second embodiment. Although the getter member 104 may have a flat surface, in the organic EL display substrate 100 according to the present embodiment, the getter member 104 has a rough surface, as illustrated in FIGS. 13 and 14. This can increase the surface area of the getter member 104 and increase adsorption capacity for contamination, thus more effectively suppressing a decrease in luminance due to contamination.

As illustrated in FIG. 14, the getter member 104 having the rough surface may have a lower layer flat portion 106 having a flat surface, and upper layer portions 107 disposed on the lower layer flat portion 106. The lower layer flat portion 106 and the upper layer portions 107 may form raised portions 108 and recessed portions 109.

FIGS. 15 and 16 are schematic cross-sectional views of a getter member in the organic EL display substrate according to the second embodiment.

The getter member 104 having a rough surface may be formed of the material used in the TFT 12 or the material used in the organic EL device 20, and may be formed by a photolithography technique in the former case and by a mask vapor deposition method in the latter case. More specifically, for example, as illustrated in FIG. 15, the getter member 104 may include a lower layer flat portion 140, which is formed by the same step as gate lines and contains a gate line material, and upper layer portions 141, which are formed by the same step as signal lines and contain a signal line material, or as illustrated in FIG. 16, may include a lower layer flat portion 142, which is formed by the same step as signal lines and contains a signal line material, and upper layer portions 143, which are formed by the same step as a silicon nitride film and contain a silicon nitride film material, that is, silicon nitride, or may include a lower layer flat portion (not shown), which is formed by the same step as signal lines and contains a signal line material, and upper layer portions (not shown), which are formed by the same step as the interlayer film 13 or the edge cover 15 and contain an organic resin material.

FIG. 17 is a schematic plan view of the organic EL display substrate according to the second embodiment.

As illustrated in FIG. 17, the getter member 104 may include a plurality of patterns 144 and 145. The patterns 144 and 145 of the getter member 104 may have different multilayer structures. For example, the patterns 144 and 145 may have multilayer structures as illustrated in FIGS. 15 and 16.

The surface roughness of the getter member 104 is not particularly limited and may be appropriately determined. For example, when an electric wire material is used, the surface roughness may have a width of several micrometers.

Although the getter member 104 having a rough surface in FIG. 13 is disposed in the entire area around the light-emitting region 102 and the vapor deposition region 103, the getter member 104 having a rough surface may be disposed in one or two places around the light-emitting region 102 and the vapor deposition region 103, as illustrated in FIG. 7 or 11.

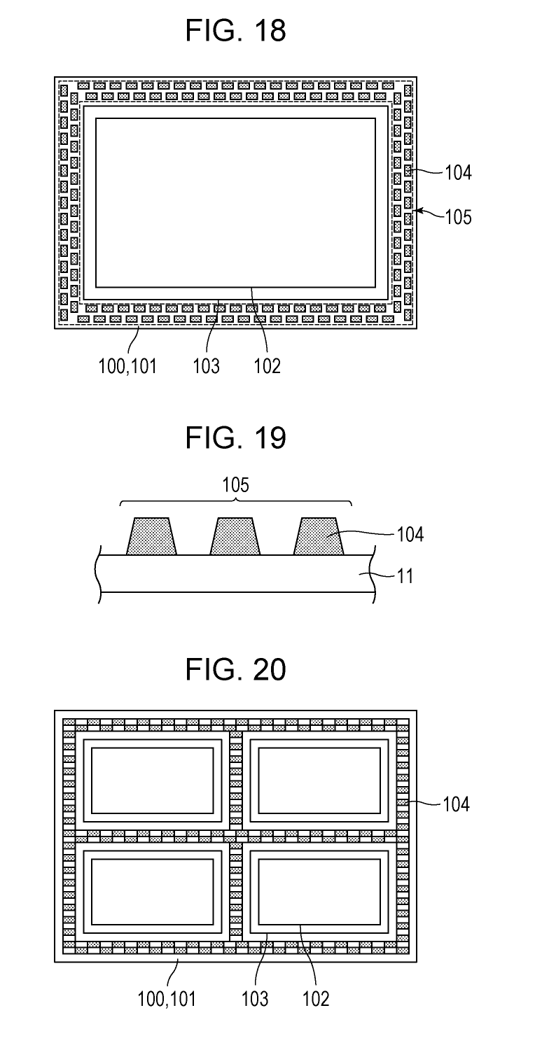

FIG. 18 is a schematic plan view of the organic EL display substrate according to the second embodiment. FIG. 19 is a schematic cross-sectional view of the organic EL display substrate according to the second embodiment.

As illustrated in FIGS. 18 and 19, the substrate 100 may include a getter member 104 having a micropattern 105, and the getter member 104 may include many fine portions.

The micropattern 105 of the getter member 104 in the substrate 100 can also increase the surface area of the getter member 104 and can more effectively suppress a decrease in luminance due to contamination.

The specific size of the micropattern 105 is not particularly limited and may be appropriately determined. For example, if the micropattern 105 is adjusted for the size of the pixels, the size of each portion of the getter member 104 may range from approximately 10 to 30 μm, and the space between adjacent portions of the getter member 104 may range from approximately 20 to 60 μm.

Although the micropattern 105 of the getter member 104 (regions in which each portion of the getter member 104 is disposed) in FIG. 18 is disposed in the entire area around the light-emitting region 102 and the vapor deposition region 103, the micropattern 105 of the getter member 104 (regions in which each portion of the getter member 104 is disposed) may be disposed in one or two places around the light-emitting region 102 and the vapor deposition region 103, as illustrated in FIG. 7 or 11.

As described above, the micropattern 105 of the getter member 104 is preferably formed simultaneously with the formation of the organic EL device 20 or the TFT 12. In this case, the micropattern 105 is also formed by the film forming method used for the formation, for example, by a mask vapor deposition method (that is, an application method with a vacuum deposition apparatus and a mask). Use of the mask vapor deposition method enables the formation of the micropattern 105 by providing the mask with an opening for the formation of the micropattern 105 of the getter member 104 in addition to the opening for pixel patterning. However, when the formation of the opening for the formation of the micropattern 105 affects the opening for pixel patterning, the getter member 104 may preferably be formed with a large pattern rather than the micropattern 105. Thus, whether the micropattern 105 is formed or not may be determined according to the situation of the film formation step of the organic EL device 20 or the TFT 12.

FIG. 20 is a schematic plan view of the organic EL display substrate according to the second embodiment.

As illustrated in FIG. 20, the substrate 100 may include a plurality of panel formation regions. In other words, the substrate 100 may include a plurality of light-emitting regions 102 and vapor deposition regions 103. The getter member 104 may be disposed in at least part of the area around each of the light-emitting regions 102 and the vapor deposition regions 103. This enables a plurality of organic EL display apparatuses to be manufactured from one substrate 100 and suppresses a decrease in luminance due to contamination in the organic EL display apparatuses manufactured at the same time.

Although the getter member 104 in FIG. 20 is disposed in the entire area around each of the light-emitting regions 102 and the vapor deposition regions 103 and has a rough surface, the getter member 104 may be disposed in one or two places around each of the light-emitting regions 102 and the vapor deposition regions 103 and may have a flat surface, as illustrated in FIG. 7 or 11.

### Third Embodiment

In the present embodiment, the distinct features of the present embodiment are mainly described, and the contents overlapping those of the first embodiment are omitted. Components having the same or similar functions in the present embodiment and the first embodiment are denoted by the same reference numerals and are not described in the present embodiment. The present embodiment is substantially the same as the first embodiment except for the points described below.

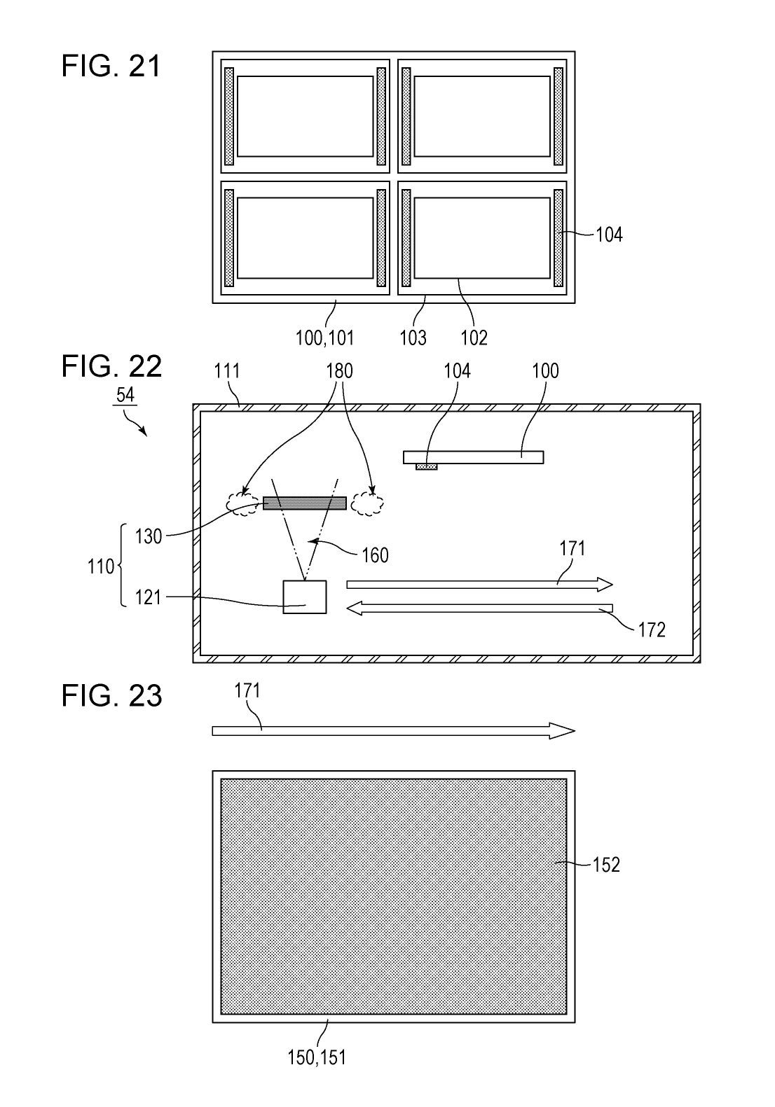

FIG. 21 is a schematic plan view of an organic EL display substrate according to a third embodiment.

As illustrated in FIG. 21, the organic EL display substrate 100 according to the present embodiment includes a plurality of light-emitting regions 102 and vapor deposition regions 103 and includes a getter member 104 in at least part of the area around each of the light-emitting regions 102. Each of the getter members 104 is disposed in the vapor deposition regions 103. Even when the getter members 104 are disposed in the vapor deposition regions 103 and the panel formation regions in this manner, the getter members 104 in a non-luminous region that does not affect the other members, such as terminals and electric wires, can adsorb contamination without problems. The getter members 104 can be closer to the light-emitting regions 102 than when the getter members 104 are disposed outside the vapor deposition regions 103. This can reduce the likelihood of contamination of the light-emitting region 102.

Although not shown in FIG. 21, in order to more effectively reduce contamination of the light-emitting region 102, if possible, the getter member 104 may be disposed outside the vapor deposition regions 103 as well as in the vapor deposition regions 103, as described in the first and second embodiments.

Although two getter members 104 are disposed around each of the light-emitting regions 102 in FIG. 21, the getter member 104 may be disposed in one place around each of the light-emitting regions 102 or in the entire area around each of the light-emitting regions 102, as described in the first and second embodiments.

### Fourth Embodiment

In the present embodiment, the distinct features of the present embodiment are mainly described, and the contents overlapping those of the first embodiment are omitted. Components having the same or similar functions in the present embodiment and the first embodiment are denoted by the same reference numerals and are not described in the present embodiment. The present embodiment is substantially the same as the first embodiment except for the points described below.

FIG. 22 is a schematic view illustrating a light-emitting layer deposition step in a method for manufacturing an organic EL display apparatus according to a fourth embodiment and illustrating an apparatus for manufacturing an organic EL display apparatus according to the fourth embodiment and is a cross-sectional view of an organic EL display substrate according to the fourth embodiment and an apparatus for manufacturing an organic EL display apparatus according to the fourth embodiment.

In an apparatus 54 for manufacturing an organic EL display apparatus according to the present embodiment (scanning deposition apparatus), a conveying mechanism (not shown) is coupled to a vapor deposition unit 110 and can convey the vapor deposition unit 110 in the direction perpendicular to the direction normal to an organic EL display substrate 100 (in a conveying direction 171) at a constant speed, as illustrated in FIG. 22. A substrate holder (not shown) is fixed to a vapor deposition chamber 111, and the substrate 100 held by the substrate holder is stationary. Thus, the conveying mechanism can convey the vapor deposition unit 110 in the conveying direction 171 relative to the substrate 100.

In the light-emitting layer deposition step S3, the conveying mechanism conveys (moves, scans) the vapor deposition unit 110 in the conveying direction 171 under the substrate 100. Consequently, in the same manner as in the first embodiment, depositing particles passing through an opening (not shown) of a mask 130 adhere one after another to the substrate 100, which moves relative to the vapor deposition unit 110, and form a deposited film, that is, a light-emitting layer (not shown), having a pattern corresponding to the opening of the mask 130.

In the present embodiment, since the conveying mechanism is coupled to the vapor deposition unit 110, contamination 180 tends to occur in the vicinity of the vapor deposition unit 110, as illustrated in FIG. 22. Thus, as the vapor deposition unit 110 is conveyed, the vapor deposition unit 110 and the contamination 180 approach the substrate 100.

In the present embodiment, therefore, the getter member 104 that can adsorb contamination is disposed in at least part of the area around a light-emitting region (not shown) on the substrate 100, in the same manner as in the first embodiment. Furthermore, the substrate 100 is placed such that the getter member 104 faces an evaporation source 121 before the light-emitting region faces the evaporation source 121, that is, such that the getter member 104 and the light-emitting region are arranged in this order in the traveling direction (in front) of the vapor deposition unit 110.

Thus, the substrate 100 including the getter member 104 can be introduced into the vapor deposition chamber 111 of the scanning deposition apparatus together with the getter member 104. Because the getter member 104 is disposed in at least part of the area around the light-emitting region 102, the vapor deposition unit 110 can be conveyed such that the getter member 104 faces the vapor deposition unit 110 including the evaporation source 121 before the light-emitting region 102 faces the vapor deposition unit 110. Thus, in the present embodiment, after the contamination 180 in the vicinity of the vapor deposition unit 110 is adsorbed by the getter member 104, the vapor deposition unit 110, the contamination 180 in the vicinity of which is adsorbed by the getter member 104, can be conveyed under the light-emitting region (not shown) and a vapor deposition region (not shown). Thus, the vapor deposition unit 110 can be conveyed and perform vacuum deposition treatment while the getter member 104 removes the contamination 180. This can reduce the contamination 180 of the light-emitting region and the vapor deposition region and suppress a decrease in luminance due to contamination.

The vapor deposition unit 110 may be conveyed under the substrate 100 by the conveying mechanism (forward) and then conveyed again in the direction opposite to the conveying direction 171 (in a conveying direction 172) (backward) under the substrate 100 by the conveying mechanism without turning the vapor deposition unit 110 around. In this case, as described in the first and second embodiments, the getter member 104 is preferably disposed in two places around each light-emitting region and vapor deposition region or in the entire area around each light-emitting region and vapor deposition region.

### Fifth Embodiment

In the present embodiment, the distinct features of the present embodiment are mainly described, and the contents overlapping those of the first embodiment are omitted. Components having the same or similar functions in the present embodiment and the first embodiment are denoted by the same reference numerals and are not described in the present embodiment. The present embodiment is substantially the same as the first embodiment except for the points described below.

FIG. 23 is a schematic plan view of a getter substrate for use in a vapor deposition step in a method for manufacturing an organic EL display apparatus according to a fifth embodiment and for use in an apparatus for manufacturing an organic EL display apparatus according to the fifth embodiment.

In the first embodiment, no getter member may be formed on the organic EL display substrate, for example, due to a large vapor deposition region. Thus, in the present embodiment, instead of a getter member on an organic EL display substrate, a getter substrate 150, which is a substrate exclusively used to adsorb contamination, is prepared and used, as illustrated in FIG. 23.

The getter substrate 150 includes a transparent insulating substrate 151, such as a glass substrate, as a supporting substrate and includes a getter member 152 substantially throughout the insulating substrate 151. The details such as functions and material of the getter member 152 are the same as the details of the getter member 104 described in the first embodiment.

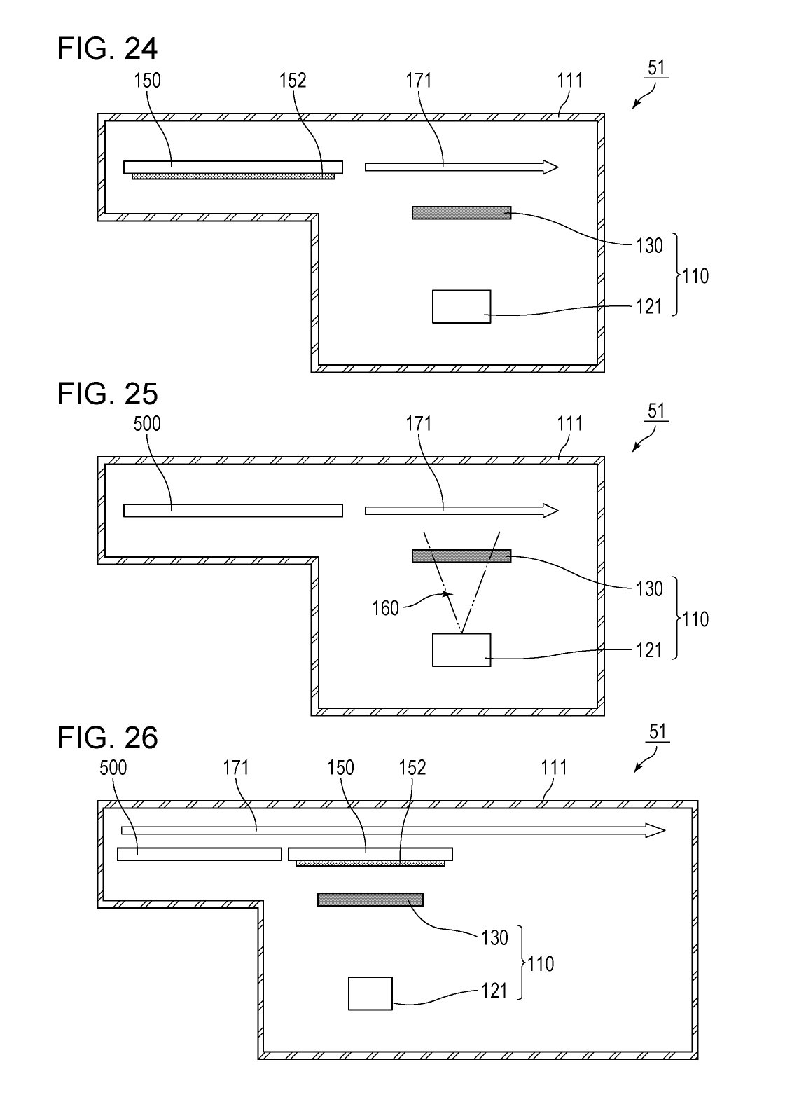

FIG. 24 is a schematic view illustrating a light-emitting layer deposition step in the method for manufacturing an organic EL display apparatus according to the fifth embodiment and illustrating the apparatus for manufacturing an organic EL display apparatus according to the fifth embodiment and is a cross-sectional view of a getter substrate and the apparatus for manufacturing an organic EL display apparatus according to the fifth embodiment. FIG. 25 is a schematic view illustrating the light-emitting layer deposition step in the method for manufacturing an organic EL display apparatus according to the fifth embodiment and illustrating the apparatus for manufacturing an organic EL display apparatus according to the fifth embodiment and is a cross-sectional view of an organic EL display substrate according to the fifth embodiment and the apparatus for manufacturing an organic EL display apparatus according to the fifth embodiment.

In the present embodiment, in a vapor deposition step, for example, in the light-emitting layer deposition step S3, as illustrated in FIG. 24, the getter substrate 150 is placed in a vapor deposition chamber 111 of a scanning deposition apparatus 51 before vapor deposition is performed on an organic EL display substrate 500 including no getter member. After that, as illustrated in FIG. 25, vapor deposition is performed on the substrate 500 in the vapor deposition chamber 111. Thus, before vapor deposition on the substrate 500, the getter member 152 of the getter substrate 150 can adsorb contamination in the vapor deposition chamber 111. After that, the substrate 500 can be conveyed in the region in which the getter member 152 of the getter substrate 150 has adsorbed contamination. This can reduce contamination of a light-emitting region (not shown) of the substrate 500 and can consequently suppress a decrease in luminance due to contamination. The substrate 500 is substantially the same as the substrate 100 except that the substrate 500 includes no getter member.

The method for manufacturing an organic EL display apparatus according to the present embodiment includes a step of preparing the getter substrate 150 including the getter member 152 that can adsorb contamination, and a vapor deposition step of performing vapor deposition on the organic EL display substrate 500 in the vapor deposition chamber 111 after the getter substrate 150 is placed in the vapor deposition chamber 111. This can suppress a decrease in luminance due to contamination, as described above.

The scanning deposition apparatus 51 according to the present embodiment is an apparatus for manufacturing an organic EL display apparatus that includes the vapor deposition chamber 111. The scanning deposition apparatus 51 according to the present embodiment performs vapor deposition on the organic EL display substrate 500 in the vapor deposition chamber 111 after the getter substrate 150 including the getter member 152 that can adsorb contamination is placed in the vapor deposition chamber 111. This can suppress a decrease in luminance due to contamination, as described above.

FIG. 26 is a schematic view illustrating the light-emitting layer deposition step in the method for manufacturing an organic EL display apparatus according to the fifth embodiment and illustrating the apparatus for manufacturing an organic EL display apparatus according to the fifth embodiment and is a cross-sectional view of a getter substrate, the organic EL display substrate according to the fifth embodiment, and the apparatus for manufacturing an organic EL display apparatus according to the fifth embodiment.

In the present embodiment, after the getter substrate 150 in the vapor deposition chamber 111 is conveyed from the vapor deposition chamber 111, as illustrated in FIG. 24, the organic EL display substrate 500 may be conveyed into the vapor deposition chamber 111 and subjected to vapor deposition, as illustrated in FIG. 25. Alternatively, as illustrated in FIG. 26, the getter substrate 150 may be followed by the organic EL display substrate 500 in the vapor deposition chamber 111. The former mode is suitable in the case where the substrate 500 is conveyed into and from the vapor deposition chamber 111 through the same part (exit and entrance). The latter mode is suitable in the case where the entrance and exit are different, and a plurality of the substrates 500 are successively conveyed into the same vapor deposition chamber 111 through the entrance and are subjected to vapor deposition treatment while conveyed in a single direction. In the former mode, the organic EL display substrate 500 is preferably conveyed into the vapor deposition chamber 111 and subjected to vapor deposition as immediately as possible after the getter substrate 150 is conveyed from the vapor deposition chamber 111. In the latter mode, the organic EL display substrate 500 is preferably conveyed as closely as possible behind the getter substrate 150, and more preferably these substrates 150 and 500 are simultaneously conveyed such that the substrate 500 is just behind the getter substrate 150. In both modes, it is not necessary to perform vapor deposition on the getter substrate 150.

The size of the getter substrate 150 is not particularly limited and may be appropriately determined. Preferably the getter substrate 150 has almost the same size as the organic EL display substrate 500 in terms of effective adsorption of contamination and handleability of the getter substrate 150 and the organic EL display substrate 500.

The getter member 152 may be placed at any location on the getter substrate 150. In terms of effective adsorption of contamination, as illustrated in FIG. 23, the getter member 152 is preferably disposed across substantially the full width of the getter substrate 150 and is more preferably disposed substantially throughout the getter substrate 150.

The planar shape of the region in which the getter member 152 is disposed is not particularly limited and may be appropriately determined; for example, the planar shape is rectangular, as illustrated in the FIG. 23. As illustrated in FIG. 23, the getter member 152 may have a continuous pattern, that is, a pattern composed of one portion, or a discontinuous pattern, that is, a pattern composed of separate portions. In the latter case, the planar shape of each portion of the getter member 152 is not particularly limited and may be appropriately determined.

The getter member 152 may have a flat surface but preferably has a rough surface as described in the second embodiment. This can increase the surface area of the getter member 152 and increase adsorption capacity for contamination, thus more effectively suppressing a decrease in luminance due to contamination.

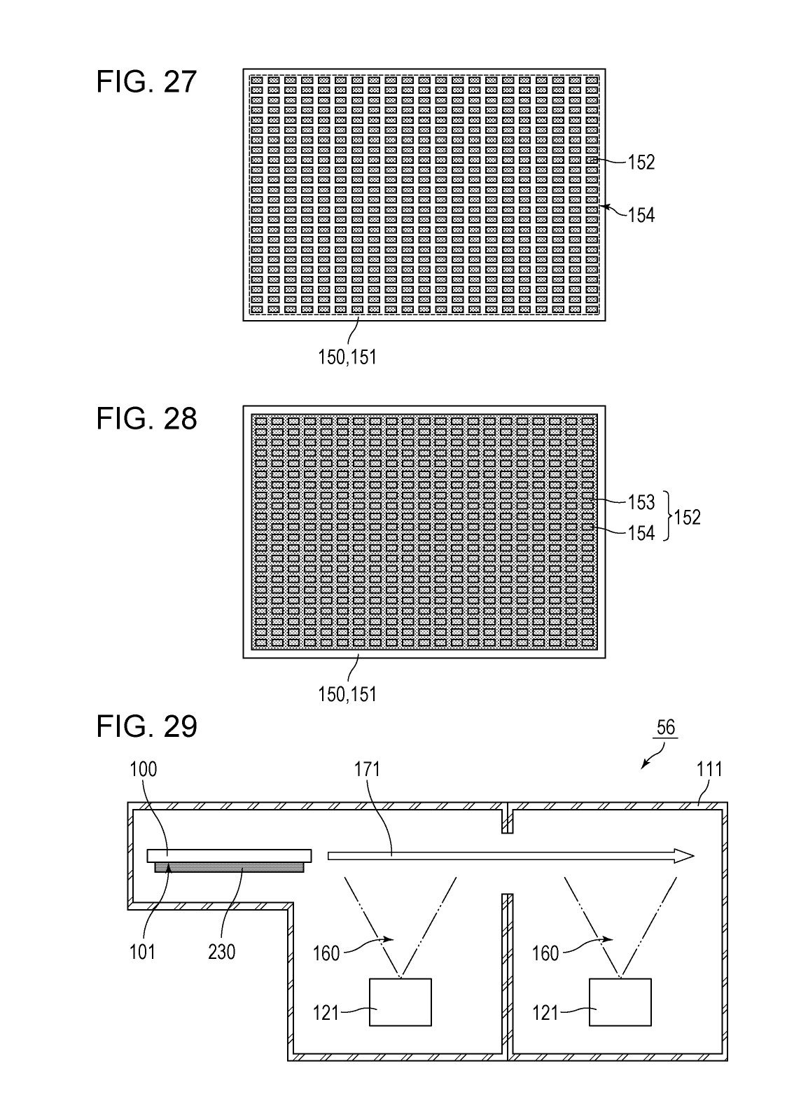

FIG. 27 is a schematic plan view of a getter substrate for use in the vapor deposition step in the method for manufacturing an organic EL display apparatus according to the fifth embodiment and for use in the apparatus for manufacturing an organic EL display apparatus according to the fifth embodiment.

As illustrated in FIG. 27 and as described in the second embodiment, the getter substrate 150 may include a getter member 152 having a micropattern 154, and the getter member 152 may have many fine portions. This can increase the surface area of the getter member 152 and can therefore more effectively suppress a decrease in luminance due to contamination.

FIG. 28 is a schematic plan view of a getter substrate for use in the vapor deposition step in the method for manufacturing an organic EL display apparatus according to the fifth embodiment and for use in the apparatus for manufacturing an organic EL display apparatus according to the fifth embodiment.

As illustrated in FIG. 28, the getter member 152 may include a film having a flat surface (flat film) 153 and a micropattern 154 formed on the flat film 153. This can also increase the surface area of the getter member 152 and can therefore more effectively suppress a decrease in luminance due to contamination.

### Sixth Embodiment

In the present embodiment, the distinct features of the present embodiment are mainly described, and the contents overlapping those of the first embodiment are omitted. Components having the same or similar functions in the present embodiment and the first embodiment are denoted by the same reference numerals and are not described in the present embodiment. The present embodiment is substantially the same as the first embodiment except for the points described below.

In the present embodiment, the vapor deposition steps S2 to S6 are performed with an in-line deposition apparatus.

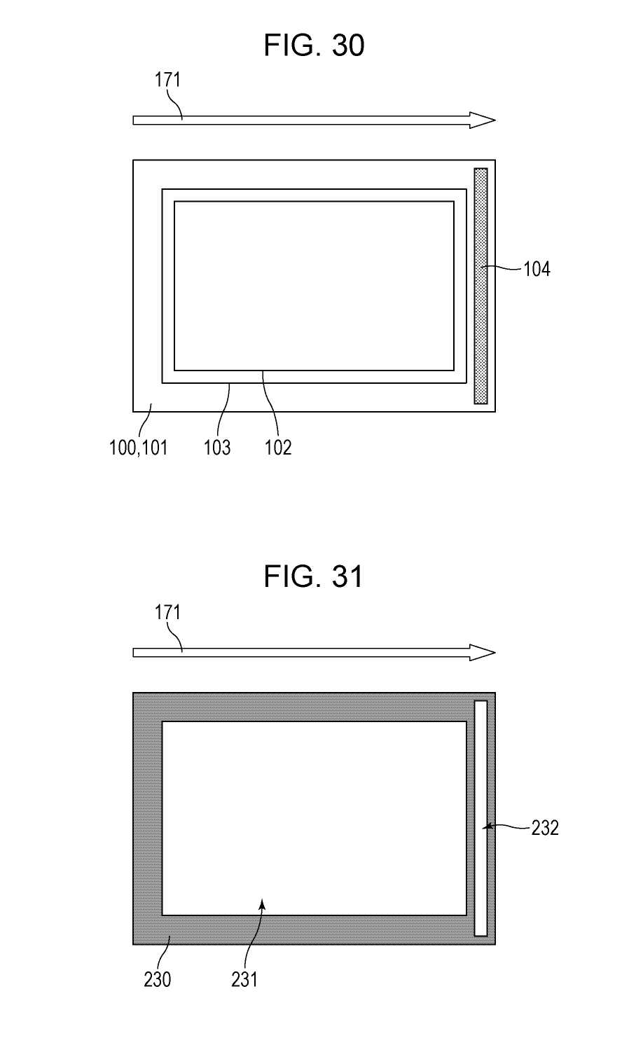

FIG. 29 is a schematic view illustrating a vapor deposition step in a method for manufacturing an organic EL display apparatus according to a sixth embodiment and illustrating an apparatus for manufacturing an organic EL display apparatus according to the sixth embodiment and is a cross-sectional view of an organic EL display substrate according to the sixth embodiment and the apparatus for manufacturing an organic EL display apparatus according to the sixth embodiment. FIG. 30 is a schematic plan view of the organic EL display substrate according to the sixth embodiment. FIG. 31 is a schematic plan view of a mask for use in the vapor deposition step in the method for manufacturing an organic EL display apparatus according to the sixth embodiment and provided in the apparatus for manufacturing an organic EL display apparatus according to the sixth embodiment.

As illustrated in FIG. 29, an apparatus 56 for manufacturing an organic EL display apparatus according to the present embodiment is a vacuum deposition apparatus, particularly an in-line deposition apparatus, and includes a vapor deposition chamber (vacuum chamber) 111, a vacuum pump (not shown), a substrate holder (not shown), a conveying mechanism (not shown), a plurality of evaporation sources 121, a mask 230, and a frame (not shown). The apparatus 56 for manufacturing an organic EL display apparatus according to the present embodiment is hereinafter also referred to as an in-line deposition apparatus 56.

As illustrated in FIG. 30 and as described in the first embodiment, an organic EL display substrate 100 according to the present embodiment includes a light-emitting region 102, a vapor deposition region 103, and a getter member 104.

As illustrated in FIG. 31, the mask 230 has almost the same size as the substrate 100 and has openings 231 and 232.

The frame is a frame-shaped reinforcing member and is welded to the mask 230.

The substrate holder holds the substrate 100, the mask 230, and the frame together such that a vapor deposition surface 101 of the substrate 100 faces the mask 230. The substrate 100 is held by the substrate holder while being in close contact with the mask 230 or frame.

The opening 231 is formed such that the light-emitting region 102 of the substrate 100 is entirely exposed while the mask 230 is held by the substrate holder. This enables vapor deposition on the entire surface of the light-emitting region 102. The dimensions of the opening 231 are substantially the same as the dimensions of the vapor deposition region 103. The opening 232 of the mask 230 corresponds to the getter member 104. The opening 232 is formed such that at least part of (preferably, the whole of) the getter member 104 is exposed while the mask 230 is held by the substrate holder. The substrate 100 is held by the substrate holder with the light-emitting region 102, the vapor deposition region 103, and the getter member 104 being exposed through the openings 231 and 232 of the mask 230.

The conveying mechanism can convey the substrate 100 and the mask 230 held by the substrate holder at a constant speed in the direction perpendicular to the direction normal to the substrate 100 (in a conveying direction 171).

The evaporation sources 121 are aligned in the conveying direction 171. The substrate 100 is continuously conveyed above the evaporation sources 121. Consequently, vapor deposition treatment is continuously performed with the evaporation sources 121, and a plurality of deposited films are stacked on the substrate 100.

Vapor deposition treatment is continuously performed with the getter member 104 being exposed through the opening 232 of the mask 230. Thus, in the same manner as in the first embodiment, the substrate 100 can be conveyed and subjected to vacuum deposition treatment while the getter member 104 adsorbs contamination, and contamination of the light-emitting region 102 and the vapor deposition region 103 can be reduced. This can suppress a decrease in luminance due to contamination.

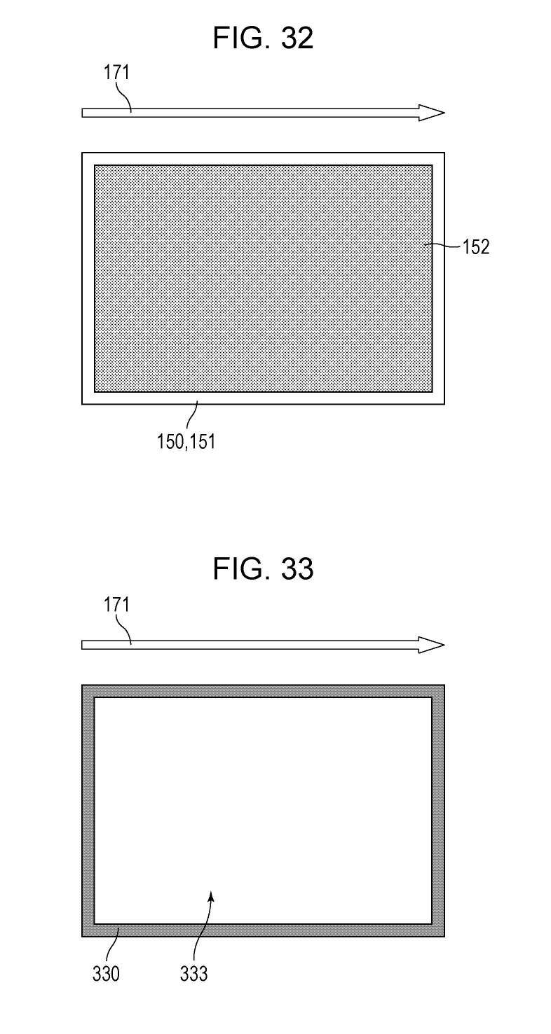

FIG. 32 is a schematic plan view of a getter substrate for use in the vapor deposition step in the method for manufacturing an organic EL display apparatus according to the sixth embodiment and for use in the apparatus for manufacturing an organic EL display apparatus according to the sixth embodiment. FIG. 33 is a schematic plan view of a mask for use in the vapor deposition step in the method for manufacturing an organic EL display apparatus according to the sixth embodiment and provided in the apparatus for manufacturing an organic EL display apparatus according to the sixth embodiment.

In the present embodiment, the getter member 104 may not be formed on the organic EL display substrate 100, for example, because the vapor deposition region 103 is large. In such a case, instead of the getter member 104 on the substrate 100, as illustrated in FIG. 32, a getter substrate 150, which is a substrate exclusively used to adsorb contamination, may be prepared and used in the same manner as in the fourth embodiment. Furthermore, as illustrated in FIG. 33, a mask 330 for the getter substrate 150 may be used.

The getter substrate 150 includes a transparent insulating substrate 151, such as a glass substrate, as a supporting substrate and includes a getter member 152 substantially throughout the insulating substrate 151.

The mask 330 has almost the same size as the getter substrate 150 and has an opening 333. The opening 333 corresponds to the getter member 152 and is formed such that at least part of (preferably, the whole of) the getter member 152 is exposed while the mask 330 is held by the substrate holder. The mask 330 is held by the substrate holder with the getter member 152 being exposed through the opening 333 of the mask 330.

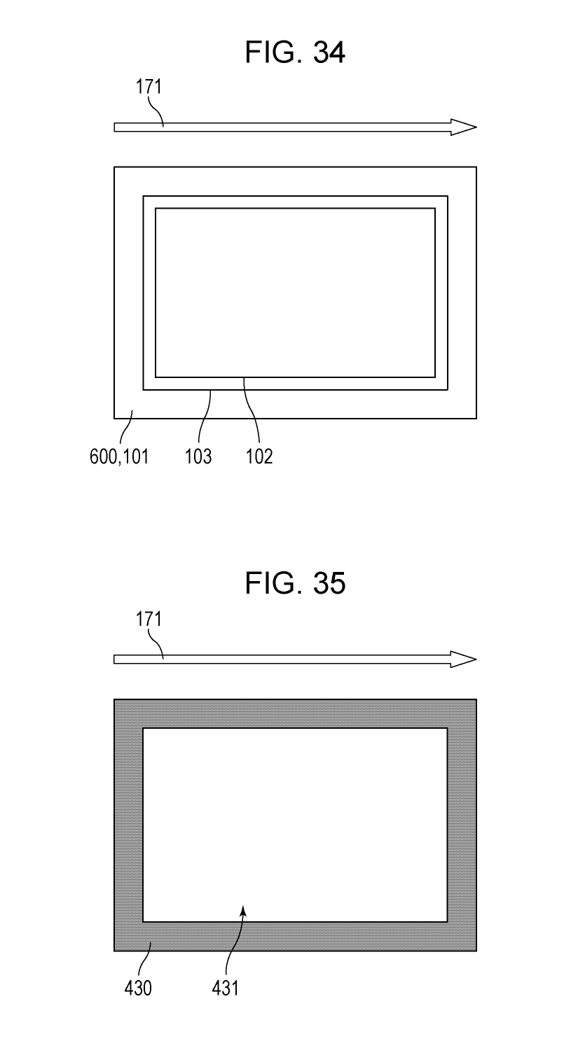

FIG. 34 is a schematic plan view of an organic EL display substrate according to the sixth embodiment. FIG. 35 is a schematic plan view of a mask for use in the vapor deposition step in the method for manufacturing an organic EL display apparatus according to the sixth embodiment and provided in the apparatus for manufacturing an organic EL display apparatus according to the sixth embodiment.

As illustrated in FIG. 34 and as described in the first embodiment, an organic EL display substrate 600 according to the present embodiment includes a light-emitting region 102 and a vapor deposition region 103, but does not necessarily include a getter member 104. In this case, the substrate 600 is substantially the same as the substrate 100 except that the substrate 600 includes no getter member.

As illustrated in FIG. 35, a mask 430 has almost the same size as the substrate 600 and has an opening 431. The opening 431 is formed such that the light-emitting region 102 of the substrate 600 is entirely exposed while the mask 430 is held by a substrate holder (not shown). This enables vapor deposition on the entire surface of the light-emitting region 102. The dimensions of the opening 431 are substantially the same as the dimensions of the vapor deposition region 103. The substrate 600 is held by the substrate holder with the light-emitting region 102 and the vapor deposition region 103 being exposed through the opening 431 of the mask 430.

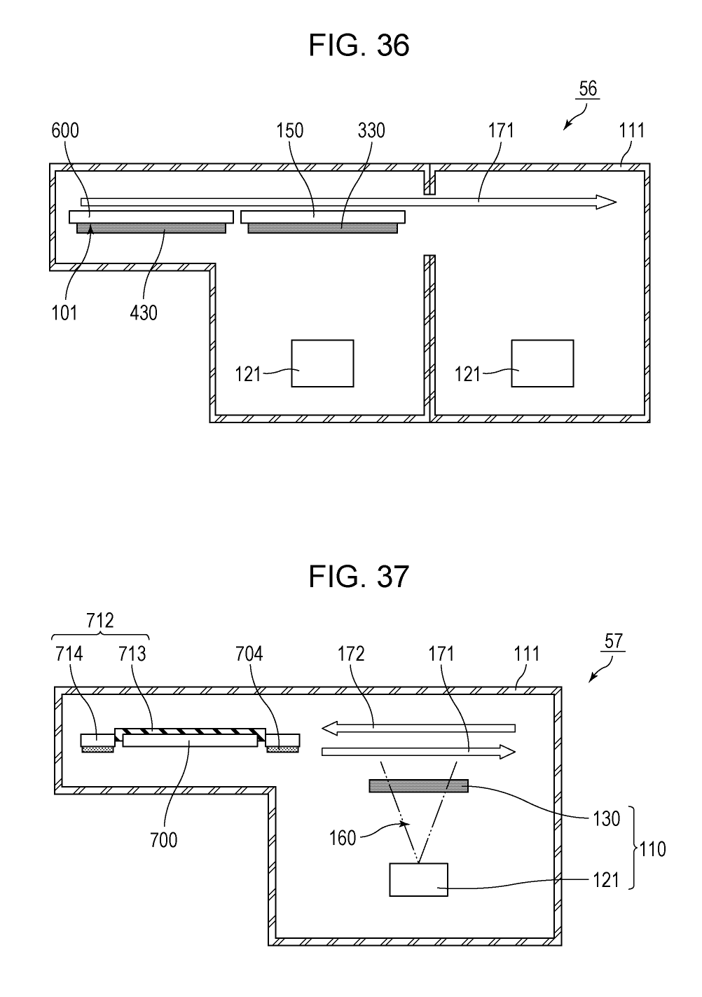

FIG. 36 is a schematic view illustrating a light-emitting layer deposition step in the method for manufacturing an organic EL display apparatus according to the sixth embodiment and illustrating the apparatus for manufacturing an organic EL display apparatus according to the sixth embodiment and is a cross-sectional view of a getter substrate, the organic EL display substrate according to the sixth embodiment, and the apparatus for manufacturing an organic EL display apparatus according to the sixth embodiment.

In the present embodiment, as illustrated in FIG. 36, after the getter substrate 150 is placed in the vapor deposition chamber 111 of the in-line deposition apparatus 56 before vapor deposition is performed on the organic EL display substrate 600 including no getter member, the organic EL display substrate 600 may be immediately subjected to vapor deposition. Thus, before vapor deposition on the substrate 600, the exposed getter member 152 of the getter substrate 150 can adsorb contamination in the vapor deposition chamber 111. This can suppress a decrease in luminance due to contamination, in the same manner as in the fourth embodiment.

From the perspective as described in the fifth embodiment, as illustrated in FIG. 36, the organic EL display substrate 600 may be conveyed behind the getter substrate 150 in the vapor deposition chamber 111, or after the getter substrate 150 in the vapor deposition chamber 111 is conveyed from the vapor deposition chamber 111, the organic EL display substrate 600 may be conveyed into the vapor deposition chamber 111 and may be subjected to vapor deposition. In the former mode, the organic EL display substrate 600 is preferably conveyed as closely as possible behind the getter substrate 150, and more preferably these substrates 150 and 600 are simultaneously conveyed such that the substrate 600 is just behind the getter substrate 150. In the latter mode, the organic EL display substrate 600 is preferably conveyed into the vapor deposition chamber 111 and subjected to vapor deposition as immediately as possible after the getter substrate 150 is conveyed from the vapor deposition chamber 111. In both modes, it is not necessary to perform vapor deposition on the getter substrate 150.

In the present embodiment, the in-line deposition apparatus 56 may be substituted by a rotary deposition apparatus. More specifically, the apparatus for manufacturing an organic EL display apparatus according to the present embodiment may be a rotary deposition apparatus and may include a point evaporation source (point source), and vapor deposition may be performed while a mask is in close contact with an organic EL display substrate and while the organic EL display substrate and mask are rotated. In general, there are fewer driving parts of rotary deposition apparatuses than driving parts of scanning deposition apparatuses and in-line deposition apparatuses. Thus, contamination in a film formation chamber can be less in the case where the apparatus for manufacturing an organic EL display apparatus according to the present embodiment is a rotary deposition apparatus than in the case where the apparatus for manufacturing an organic EL display apparatus according to the present embodiment is the scanning deposition apparatus 51 or 54 or the in-line deposition apparatus 56. However, contamination of a light-emitting region of an organic EL display substrate can be reduced by conveying an organic EL display substrate into a vapor deposition chamber and performing vapor deposition after the getter substrate 150 is placed in a film formation chamber of a rotary deposition apparatus and is conveyed from the film formation chamber.

Although the characteristic vapor deposition step in the present embodiment, that is, the vapor deposition step in which the substrate 100 including the getter member 104 or the getter substrate 150 including the getter member 152 is used may be applied to any of the vapor deposition steps S2 to S6, the characteristic vapor deposition step is particularly suitable for a step of performing vapor deposition on the entire surface of the light-emitting region 102, for example, the hole-injection layer and hole-transport layer deposition step S2, the electron-transport layer deposition step S4, the electron-injection layer deposition step S5, and the second electrode deposition step S6. Likewise, although the apparatus for manufacturing an organic EL display apparatus according to the present embodiment (the in-line deposition apparatus 56 or a rotary deposition apparatus) may be used any of the vapor deposition steps S2 to S6, the apparatus for manufacturing an organic EL display apparatus according to the present embodiment is particularly suitable for a step of performing vapor deposition on the entire surface of the light-emitting region 102, for example, the hole-injection layer and hole-transport layer deposition step S2, the electron-transport layer deposition step S4, the electron-injection layer deposition step S5, and the second electrode deposition step S6.

### Seventh Embodiment

In the present embodiment, the distinct features of the present embodiment are mainly described, and the contents overlapping those of the first embodiment are omitted. Components having the same or similar functions in the present embodiment and the first embodiment are denoted by the same reference numerals and are not described in the present embodiment. The present embodiment is substantially the same as the first embodiment except for the points described below.

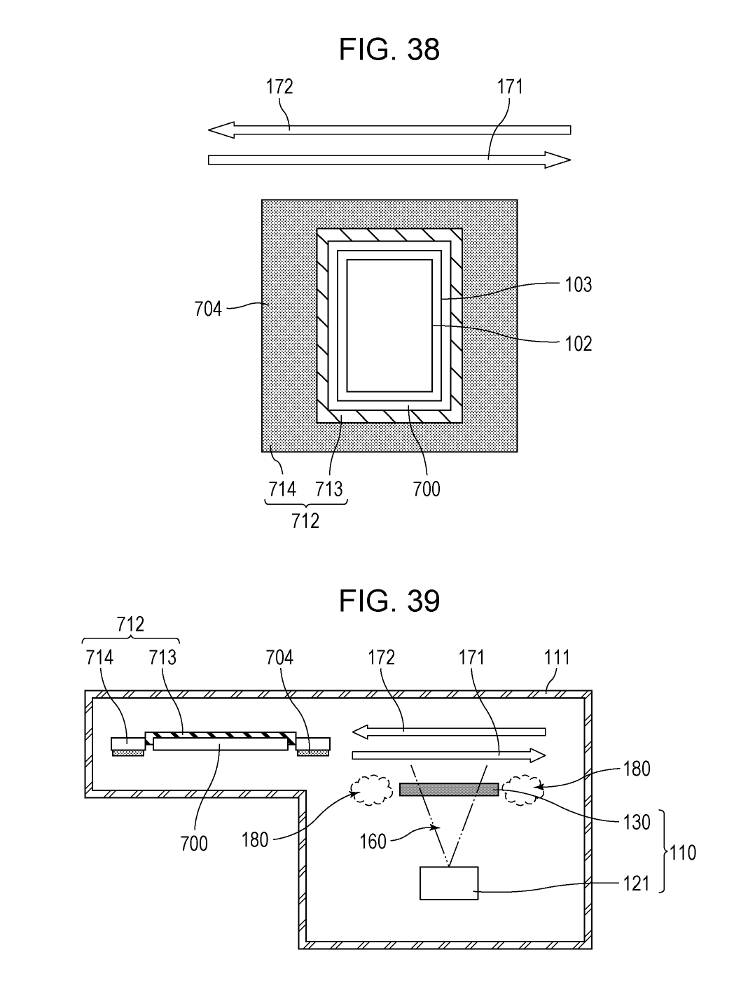

FIG. 37 is a schematic view illustrating a light-emitting layer deposition step in a method for manufacturing an organic EL display apparatus according to a seventh embodiment and illustrating an apparatus for manufacturing an organic EL display apparatus according to the seventh embodiment and is a cross-sectional view of an organic EL display substrate and the apparatus for manufacturing an organic EL display apparatus according to the seventh embodiment. FIG. 38 is a schematic view illustrating the light-emitting layer deposition step in the method for manufacturing an organic EL display apparatus according to the seventh embodiment and illustrating the apparatus for manufacturing an organic EL display apparatus according to the seventh embodiment and is a plan view of the organic EL display substrate and the apparatus for manufacturing an organic EL display apparatus according to the seventh embodiment.

In the first embodiment, no getter member may be formed on the organic EL display substrate, for example, due to a large vapor deposition region. Thus, in the present embodiment, as illustrated in FIGS. 37 and 38, instead of a getter member on an organic EL display substrate 700, a getter member 704 is disposed on a relative moving portion 712. FIG. 38 is viewed from an evaporation source side (a lower position). The substrate 700 is substantially the same as the substrate 100 except that the substrate 700 includes no getter member.

As illustrated in FIG. 37, an apparatus 57 for manufacturing an organic EL display apparatus according to the present embodiment (scanning deposition apparatus) includes an electrostatic chuck 713 as the relative moving portion 712, an anti-adhesion plate 714, and a transfer tray (not shown) in a vapor deposition chamber 111. The electrostatic chuck 713 is disposed on the transfer tray.

The relative moving portion 712 is disposed in at least part (part or the whole) of the area around the substrate 700 so as not to cover a vapor deposition region 103 of the substrate 700. The relative moving portion 712 is coupled to a conveying mechanism, is placed in the vapor deposition chamber 111, and can be conveyed by the conveying mechanism.

The anti-adhesion plate 714 is a plate-like member having a central opening, is disposed in the entire area around the substrate 700, and prevents depositing particles from unnecessarily adhering to a portion in the vapor deposition chamber 111. The anti-adhesion plate 714 is coupled to the transfer tray. The anti-adhesion plate 714 may be disposed in part of the area around the substrate 700.

The conveying mechanism is coupled to the transfer tray and can convey the transfer tray, the electrostatic chuck 713 and the anti-adhesion plate 714 disposed on the transfer tray, and the substrate 700 held (adsorbed) by the electrostatic chuck 713 in an integrated manner at a constant speed. A vapor deposition unit 110 is fixed to the vapor deposition chamber 111 and is stationary. Thus, the conveying mechanism can simultaneously move the substrate 700 and the relative moving portion 712 (the electrostatic chuck 713, the anti-adhesion plate 714, and the transfer tray) in a predetermined direction relative to the vapor deposition unit 110. While the conveying mechanism conveys the substrate 700 and the relative moving portion 712 (during vapor deposition), the relative position of the relative moving portion 712 with respect to the substrate 700 is unchanged.

In the light-emitting layer deposition step S3, the scanning deposition apparatus 57 may convey the substrate 700 over the evaporation source 121 by the conveying mechanism only in the direction perpendicular to the direction normal to the substrate 700 (in a conveying direction 171), or may convey the substrate 700 over the evaporation source 121 in the conveying direction 171 (forward) by the conveying mechanism and then convey the substrate 700 over the evaporation source 121 again in the direction opposite to the conveying direction 171 (in a conveying direction 172) (backward) by the conveying mechanism without turning the substrate 700 around. In the latter case, vapor deposition treatment can be performed while the substrate 700 moves forward and backward over the evaporation source 121. Furthermore, the substrate 700 can be conveyed into and from the vapor deposition chamber 111 through the same part (exit and entrance).

As illustrated in FIGS. 37 and 38, the getter member 704 is disposed on substantially the entire lower surface (a surface facing the evaporation source 121) of the anti-adhesion plate 714. The details such as functions and material of the getter member 704 are the same as the details of the getter member 104 described in the first embodiment.

As illustrated in FIG. 38, the getter member 704 may have a continuous pattern, that is, a pattern composed of one portion, or a discontinuous pattern, that is, a pattern composed of separate portions. In the latter case, each portion of the getter member 704 may have any planar shape and may be appropriately determined.

FIG. 39 is a schematic view illustrating a light-emitting layer deposition step in a method for manufacturing an organic EL display apparatus according to Comparative Embodiment 2 and is a cross-sectional view of an organic EL display substrate and a scanning deposition apparatus.

Comparative Embodiment 2 is substantially the same as the seventh embodiment except that the anti-adhesion plate includes no getter member. As illustrated in FIG. 39, in Comparative Embodiment 2, the substrate 700 is conveyed through contamination 180 in the vapor deposition chamber 111. Thus, the entire surface of the substrate 700 is contaminated, resulting in low luminance.

By contrast, in the present embodiment, as illustrated in FIGS. 37 and 38, the getter member 704 on the anti-adhesion plate 714 is disposed in the entire area around each of the light-emitting region 102 and the substrate 700. Thus, the getter member 704 is disposed in at least part of the area around the light-emitting region 102.

Since the getter member 704 is disposed on the anti-adhesion plate 714, that is, on the relative moving portion 712, the substrate 700, together with the getter member 704, can be introduced into the vapor deposition chamber 111 of the scanning deposition apparatus 57. Because the getter member 704 is disposed in at least part of the area around the light-emitting region 102, the substrate 700 can be conveyed such that the getter member 704 faces the vapor deposition unit 110 including the evaporation source 121 before the light-emitting region 102 faces the vapor deposition unit 110. Thus, in the present embodiment, while the substrate 700 is conveyed, the getter member 704 can precede the light-emitting region 102. The getter member 704 can adsorb contamination while moving through the contamination region, and thereafter the substrate 700 including the light-emitting region 102 and the vapor deposition region 103 can move through the region in which the getter member 704 has adsorbed contamination. In the same manner as in the first embodiment, this can reduce contamination of the light-emitting region 102 and the vapor deposition region 103 and consequently suppress a decrease in luminance due to contamination.

Although the area of the getter member 104 in the first embodiment is limited on the organic EL display substrate 100, the getter member 704 in the present embodiment is not disposed on the organic EL display substrate 700 but is disposed on the relative moving portion 712. Thus, the area of the getter member 704 can be larger than the area of the getter member 104. Thus, the area of the region that can adsorb contamination can be larger in the present embodiment than in the first embodiment. Contamination can therefore be more efficiently adsorbed in the present embodiment.

The getter member 704 is not disposed on the substrate 700 but is disposed on the relative moving portion 712. Thus, contamination of the getter member 704 does no adversely affect the characteristics of the organic EL device 20.

Because the getter member 704 is disposed in the vapor deposition chamber 111, unlike the case where the technical idea described in Patent Literature 1 is applied to the vacuum deposition method as described above, no large exhaust system is required.

The getter member 704 is disposed on the relative moving portion 712 in at least part of the area around the substrate 700 and, together with the substrate 700, is disposed in the vapor deposition chamber 111. Thus, unlike the case where the technical idea described in Patent Literature 1 is applied to the vacuum deposition method as described above, contamination in the vapor deposition chamber 111 can be effectively prevented from adhering to the light-emitting region 102 and the vapor deposition region 103.

The getter member 704 disposed in the entire area around the light-emitting region 102 can reduce contamination of the substrate 700 while the substrate 700 moves forward and backward in the conveying directions 171 and 172. The getter member 704 can also reduce contamination in the direction perpendicular to the conveying directions 171 and 172 and can more effectively reduce contamination of the light-emitting region 102 and the vapor deposition region 103. From the same perspective, the getter member 704 is preferably disposed in the entire area around the vapor deposition region 103 and is preferably disposed in the entire area around the substrate 700.

As described above, the method for manufacturing an organic EL display apparatus according to the present embodiment includes a vapor deposition step of depositing a material released from the evaporation source 121 onto the organic EL display substrate 700 including the light-emitting region 102 containing a plurality of pixels while conveying either the organic EL display substrate 700 and the relative moving portion 712 in the vapor deposition chamber 111 or the evaporation source 121 that vaporizes and releases the material or both to move the substrate 700 and the relative moving portion 712 relative to the evaporation source 121, wherein in the vapor deposition step, either the substrate 700 and the relative moving portion 712 or the evaporation source 121 or both are conveyed such that the getter member 704 that is disposed in at least part of the area around the light-emitting region 102 and can adsorb contamination faces the evaporation source 121 before the light-emitting region 102 faces the evaporation source 121, and the getter member 704 is disposed on the relative moving portion 712. As described above, this can efficiently suppress a decrease in luminance due to contamination and prevent contamination of the getter member 704 from adversely affecting the characteristics of the organic EL device 20.

The scanning deposition apparatus 57 according to the present embodiment is an apparatus for manufacturing the organic EL display substrate 700. The substrate 700 includes the light-emitting region 102 containing a plurality of pixels. The scanning deposition apparatus 57 according to the present embodiment includes the vapor deposition chamber 111, the evaporation source 121 that vaporizes and releases a material, the relative moving portion 712 in the vapor deposition chamber 111, and the getter member 704 that is disposed in at least part of the area around the light-emitting region 102 and can adsorb contamination. The material released from the evaporation source 121 is deposited onto the substrate 700 while either the substrate 700 and the relative moving portion 712 or the evaporation source 121 or both are conveyed to move the substrate 700 and the relative moving portion 712 relative to the evaporation source 121. Either the substrate 700 and the relative moving portion 712 or the evaporation source 121 or both are conveyed such that the getter member 704 faces the evaporation source 121 before the light-emitting region 102 faces the evaporation source 121, and the getter member 704 is disposed on the relative moving portion 712. As described above, this can efficiently suppress a decrease in luminance due to contamination and prevent contamination of the getter member 704 from adversely affecting the characteristics of the organic EL device 20.

A modified example of the seventh embodiment will be described below.

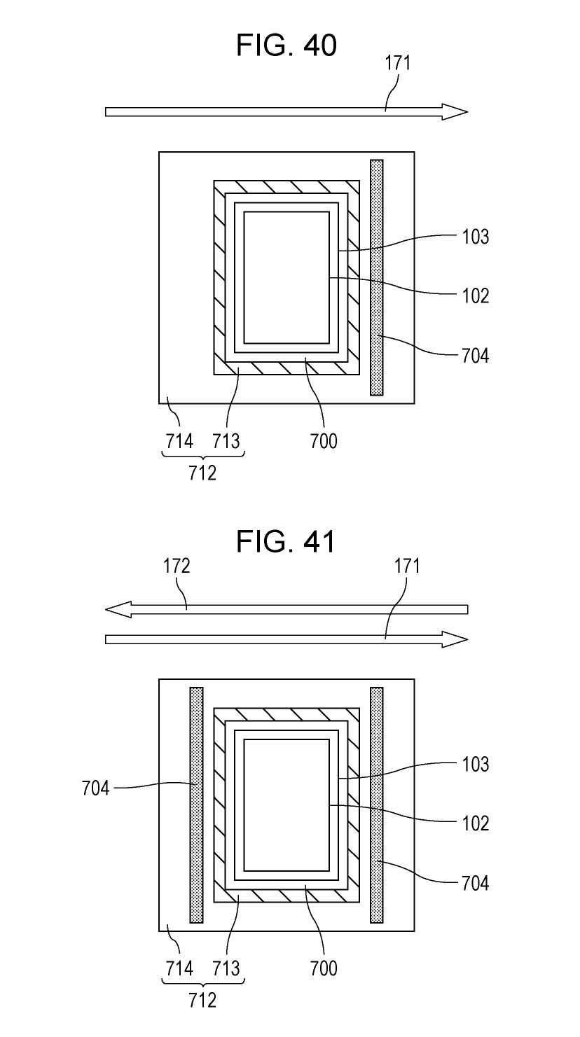

FIG. 40 is a schematic view illustrating a light-emitting layer deposition step in a method for manufacturing an organic EL display apparatus according to a modified example of the seventh embodiment and illustrating an apparatus for manufacturing an organic EL display apparatus according to the modified example of the seventh embodiment and is a plan view of an organic EL display substrate and the apparatus for manufacturing an organic EL display apparatus according to the modified example of the seventh embodiment.

When the substrate 700 and the relative moving portion 712 are conveyed only in the conveying direction 171, as illustrated in FIG. 40, the getter member 704 may be disposed along one side of each of the light-emitting region 102, the vapor deposition region 103, and the substrate 700. In this case, the getter member 704 is placed such that the getter member 704 faces the evaporation source 121 before the light-emitting region 102 faces the evaporation source 121, that is, such that the getter member 704 is located in the traveling direction (in front) of the light-emitting region 102, the vapor deposition region 103, and the substrate 700. FIG. 40 is viewed from an evaporation source side (a lower position).

The getter member 704 may be placed on any part of the relative moving portion 712 in at least part of the area around the light-emitting region 102. The getter member 704 is preferably disposed across the full width of the light-emitting region 102, more preferably across the full width of the vapor deposition region 103, still more preferably across the full width of the substrate 700. Thus, contamination can be effectively reduced throughout the light-emitting region 102 or the vapor deposition region 103. From the same perspective, the width of the region of the getter member 704 may be greater than the width of the light-emitting region 102, the vapor deposition region 103, or the substrate 700 in the direction perpendicular to the conveying direction 171. In the case where the light-emitting region 102 is rectangular and has a pair of long sides and a pair of short sides, the getter member 704 may be disposed along at least the full length of a long side of the light-emitting region 102 or the full length of a short side of the light-emitting region 102. In the case where the vapor deposition region 103 is rectangular and has a pair of long sides and a pair of short sides, the getter member 704 may be disposed along at least the full length of a long side of the vapor deposition region 103 or the full length of a short side of the vapor deposition region 103. In the case where the substrate 700 is rectangular and has a pair of long sides and a pair of short sides, the getter member 704 may be disposed along at least the full length of a long side of the substrate 700 or the full length of a short side of the substrate 700. The full length of a long side is from one end to the other end of the long side.

In the present modified example, the getter member 704 may have any planar shape and, as illustrated in FIG. 40, may be linear, for example, in a linear band shape. As illustrated in FIG. 40, the getter member 704 may have a continuous pattern, that is, a pattern composed of one portion, or a discontinuous pattern, that is, a pattern composed of separate portions. In the latter case, each portion of the getter member 704 may have any planar shape and may be appropriately determined.

FIG. 41 is a schematic view illustrating a light-emitting layer deposition step in a method for manufacturing an organic EL display apparatus according to a modified example of the seventh embodiment and illustrating an apparatus for manufacturing an organic EL display apparatus according to the modified example of the seventh embodiment and is a plan view of an organic EL display substrate and the apparatus for manufacturing an organic EL display apparatus according to the modified example of the seventh embodiment.

When the substrate 700 and the relative moving portion 712 move forward and backward in the conveying directions 171 and 172, and the getter member 704 is disposed only in one place around the light-emitting region 102 as illustrated in FIG. 40, the light-emitting region 102 may be contaminated while moving backward. Thus, in the present modified example, as illustrated in FIG. 41, the getter member 704 is disposed on both sides of each of the light-emitting region 102, the vapor deposition region 103, and the substrate 700. The light-emitting region 102, the vapor deposition region 103, and the substrate 700 are disposed between the two getter members 103. The getter members 704 are disposed along two opposite sides (for example, a pair of long sides) of the light-emitting region 102, two opposite sides (for example, a pair of long sides) of the vapor deposition region 103, and two opposite sides (for example, a pair of long sides) of the substrate 700. FIG. 41 is viewed from an evaporation source side (a lower position).

Thus, the getter members 704 disposed in two opposite parts of the area around the light-emitting region 102 with the light-emitting region 102 interposed therebetween can adsorb contamination while the substrate 700 is conveyed not only forward but also backward. Thus, in the mode of vacuum deposition with the substrate 700 moving forward and backward over the evaporation source 121 and/or in the mode of the substrate 700 being conveyed into and from the vapor deposition chamber 111 through the same part, contamination of the light-emitting region 102 and the vapor deposition region 103 can be reduced. From the same perspective, the getter member 704 is preferably disposed on two opposite portions around the vapor deposition region 103 with the vapor deposition region 103 interposed therebetween and is preferably disposed on two opposite portions around the substrate 700 with the substrate 700 interposed therebetween.

As illustrated in FIG. 41, each of the getter members 704 is preferably disposed across the full width of the light-emitting region 102, more preferably across the full width of the vapor deposition region 103, still more preferably across the full width of the substrate 700. Thus, contamination can be effectively reduced throughout the light-emitting region 102 or the vapor deposition region 103. From the same perspective, the width of each region of the getter members 704 may be greater than the width of the light-emitting region 102, the vapor deposition region 103, or the substrate 700 in the direction perpendicular to the conveying direction 171 or 172. In the case where the light-emitting region 102 is rectangular and has a pair of long sides and a pair of short sides, each of the getter members 704 may be disposed along at least the full length of its adjacent long side of the pair of long sides of the light-emitting region 102 or the full length of its adjacent short side of the pair of short sides of the light-emitting region 102. In the case where the vapor deposition region 103 is rectangular and has a pair of long sides and a pair of short sides, each of the getter members 704 may be disposed along at least the full length of its adjacent long side of the pair of long sides of the vapor deposition region 103 or the full length of its adjacent short side of the pair of short sides of the vapor deposition region 103. In the case where the substrate 700 is rectangular and has a pair of long sides and a pair of short sides, each of the getter members 704 may be disposed along at least the full length of its adjacent long side of the pair of long sides of the substrate 700 or the full length of its adjacent short side of the pair of short sides of the substrate 700.

As illustrated in FIGS. 40 and 41, the getter member 704 may be disposed in part of the area around each of the light-emitting region 102, the vapor deposition region 103, and the substrate 700 or may be disposed on a lower surface of the anti-adhesion plate 714.

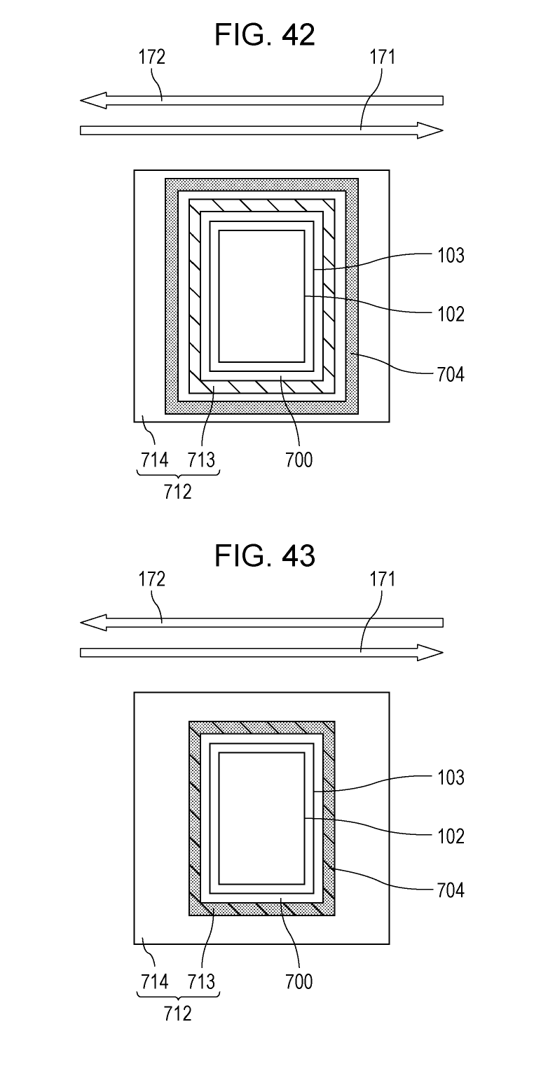

FIG. 42 is a schematic view illustrating a light-emitting layer deposition step in a method for manufacturing an organic EL display apparatus according to a modified example of the seventh embodiment and illustrating an apparatus for manufacturing an organic EL display apparatus according to the modified example of the seventh embodiment and is a plan view of an organic EL display substrate and the apparatus for manufacturing an organic EL display apparatus according to the modified example of the seventh embodiment.

When the getter member 704 is disposed on part of a lower surface of the anti-adhesion plate 714, as illustrated in FIG. 42, the getter member 704 may be a frame surrounding the light-emitting region 102, the vapor deposition region 103, and the substrate 700. FIG. 42 is viewed from an evaporation source side (a lower position).

The getter member 704 disposed in the entire area around the light-emitting region 102 can have the same effects as the modified example. The getter member 704 can also reduce contamination in the direction perpendicular to the conveying directions 171 and 172. This can more effectively reduce contamination of the light-emitting region 102 and the vapor deposition region 103 than the modified example and consequently more effectively suppress a decrease in luminance due to contamination.

The getter member 704 may include a portion evenly covering the entire lower surface of the anti-adhesion plate 714 and a portion having an appropriately designed pattern. For example, the getter member 704 may include a lower layer portion having a pattern as illustrated in FIG. 38 and an upper layer portion having a pattern as illustrated in FIGS. 40 to 42 on the lower layer portion.

The getter member 704 may have a flat surface but preferably has a rough surface as described in the second embodiment. In the same manner as in the second embodiment, a micropattern of the getter member 704 may be formed on the anti-adhesion plate 714 (the relative moving portion 712), and the getter member 704 may include many fine portions. This can increase the surface area of the getter member 704 and increase adsorption capacity for contamination, thus more effectively suppressing a decrease in luminance due to contamination.

### Eighth Embodiment

The present embodiment is substantially the same as the seventh embodiment except that the location of the getter member is different. In the present embodiment, the distinct features of the present embodiment are mainly described, and the contents overlapping those of the seventh embodiment are omitted. Components having the same or similar functions in the present embodiment and the first and seventh embodiments are denoted by the same reference numerals and are not described in the present embodiment.

FIG. 43 is a schematic view illustrating a light-emitting layer deposition step in a method for manufacturing an organic EL display apparatus according to an eighth embodiment and illustrating an apparatus for manufacturing an organic EL display apparatus according to the eighth embodiment and is a plan view of an organic EL display substrate and the apparatus for manufacturing an organic EL display apparatus according to the eighth embodiment.

As illustrated in FIG. 43, in the present embodiment, the getter member 704 is not disposed on the anti-adhesion plate 714 but on the electrostatic chuck 713. FIG. 43 is viewed from an evaporation source side (a lower position).

The electrostatic chuck 713 is a member for holding the substrate 700, includes an electrode (not shown) and an insulating film (not shown) for protecting the electrode, and causes an imbalance in positive or negative charge on the electrode. This induces opposite charges near a contact surface of the substrate 700, causes electrical attraction between the electrostatic chuck 713 and the substrate 700, and causes the substrate 700 to be adsorbed and fixed to the electrostatic chuck 713.

When viewed from the top, the electrostatic chuck 713 is larger than the substrate 700, and the substrate 700 is in contact with the center of the electrostatic chuck 713. While the substrate 700 is held by the electrostatic chuck 713, the periphery of the electrostatic chuck 713 is not entirely covered with the substrate 700 and extends out of the substrate 700.

In the present embodiment, the getter member 704 is disposed on substantially the entire periphery of the electrostatic chuck 713 and is formed in a frame surrounding the light-emitting region 102, the vapor deposition region 103, and the substrate 700. Thus, the getter member 704 is disposed in at least part of the area around the light-emitting region 102.

Since the getter member 704 is disposed on the electrostatic chuck 713, that is, on the relative moving portion 712, the substrate 700, together with the getter member 704, can be introduced into the vapor deposition chamber 111. Because the getter member 704 is disposed in at least part of the area around the light-emitting region 102, the substrate 700 can be conveyed such that the getter member 704 faces the vapor deposition unit 110 including the evaporation source 121 before the light-emitting region 102 faces the vapor deposition unit 110. In the same manner as in the seventh embodiment, this can reduce contamination of the light-emitting region 102 and the vapor deposition region 103 and consequently suppress a decrease in luminance due to contamination.

The getter member 704 can adsorb contamination nearer to the substrate 700 in the present embodiment than in the seventh embodiment and can more efficiently adsorb contamination.

The insulating film of the electrostatic chuck 713 is formed of a material such as polyimide and is likely to adsorb contamination such as an atmospheric component. The getter member 704 on the electrostatic chuck 713 can effectively trap contamination from the insulating film of the electrostatic chuck 713. Thus, when the electrostatic chuck 713 is used as a substrate holder, the present embodiment can effectively prevent contamination of the light-emitting region 102 and the vapor deposition region 103.

Although the getter member 704 in FIG. 43 is disposed in the entire area around each of the light-emitting region 102, the vapor deposition region 103, and the substrate 700, the getter member 704 may be disposed in one or two places around each of the light-emitting region 102, the vapor deposition region 103, and the substrate 700, as illustrated in FIG. 40 or 41.

The getter member 704 may include a portion evenly covering the entire periphery of the electrostatic chuck 713 and a portion having an appropriately designed pattern. For example, the getter member 704 may include a lower layer portion having a pattern as illustrated in FIG. 43 and an upper layer portion having an appropriately designed pattern on the lower layer portion.

The getter member 704 may have a flat surface but preferably has a rough surface as described in the second embodiment. In the same manner as in the second embodiment, a micropattern of the getter member 704 may be formed on the electrostatic chuck 713 (the relative moving portion 712), and the getter member 704 may include many fine portions. This can increase the surface area of the getter member 704 and increase adsorption capacity for contamination, thus more effectively suppressing a decrease in luminance due to contamination.

### Ninth Embodiment

The present embodiment is substantially the same as the seventh embodiment except that the location of the getter member is different. In the present embodiment, the distinct features of the present embodiment are mainly described, and the contents overlapping those of the seventh embodiment are omitted. Components having the same or similar functions in the present embodiment and the first and seventh embodiments are denoted by the same reference numerals and are not described in the present embodiment.

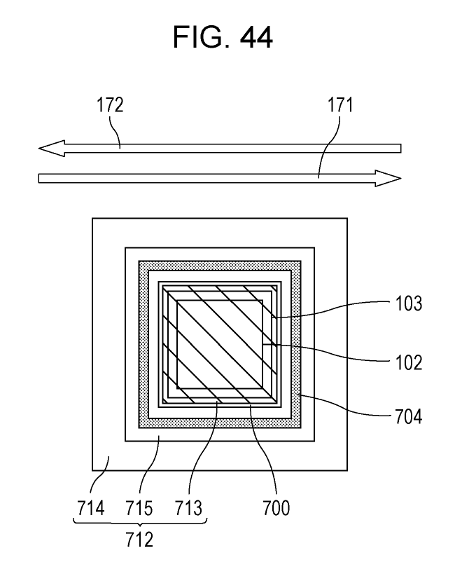

FIG. 44 is a schematic view illustrating a light-emitting layer deposition step in a method for manufacturing an organic EL display apparatus according to a ninth embodiment and illustrating an apparatus for manufacturing an organic EL display apparatus according to the ninth embodiment and is a plan view of an organic EL display substrate and the apparatus for manufacturing an organic EL display apparatus according to the ninth embodiment.

As illustrated in FIG. 44, in the present embodiment, the getter member 704 is not disposed on the anti-adhesion plate 714 but on a transfer tray 715. FIG. 44 is viewed from an evaporation source side (a lower position).

The transfer tray 715 is a rectangular member when viewed from the top and, as described above, couples the electrostatic chuck 713 and the anti-adhesion plate 714 to a conveying mechanism. Thus, the conveying mechanism can move the transfer tray 715, the electrostatic chuck 713, and the anti-adhesion plate 714, as well as the substrate 700 held (adsorbed) by the electrostatic chuck 713, relative to the vapor deposition unit 110.

In the present embodiment, when viewed from the top, the electrostatic chuck 713 is smaller than the substrate 700 and is in contact with the center (a portion other than the periphery) of the substrate 700. When viewed from the top, the transfer tray 715 is larger than the substrate 700, and there is a frame-like space between the anti-adhesion plate 714 and the substrate 700. Thus, while the substrate 700 is held by the electrostatic chuck 713, the transfer tray 715 has an exposed portion between the anti-adhesion plate 714 and the substrate 700, when viewed from the top.

In the present embodiment, the getter member 704 is disposed on the exposed portion of the transfer tray 715 and is formed in a frame surrounding the light-emitting region 102, the vapor deposition region 103, and the substrate 700. Thus, the getter member 704 is disposed in at least part of the area around the light-emitting region 102.

Since the getter member 704 is disposed on the transfer tray 715, that is, on the relative moving portion 712, the substrate 700, together with the getter member 704, can be introduced into the vapor deposition chamber 111. Because the getter member 704 is disposed in at least part of the area around the light-emitting region 102, the substrate 700 can be conveyed such that the getter member 704 faces the vapor deposition unit 110 including the evaporation source 121 before the light-emitting region 102 faces the vapor deposition unit 110. In the same manner as in the seventh embodiment, this can reduce contamination of the light-emitting region 102 and the vapor deposition region 103 and consequently suppress a decrease in luminance due to contamination.

The getter member 704 can adsorb contamination nearer to the substrate 700 in the present embodiment than in the seventh embodiment and can more efficiently adsorb contamination.

In the seventh embodiment, when the anti-adhesion plate 714 including the getter member 704 is installed in the scanning deposition apparatus 57, the installation is performed in the air, and the contamination adsorption effects of the getter member 704 are considerably decreased. In the seventh embodiment, when the getter member 704 is formed on the anti-adhesion plate 714 in a vacuum, the getter member 704 may not be formed on part of the anti-adhesion plate 714 placed at a certain location, thus resulting in insufficient effects of inhibiting contamination of the substrate 700. By contrast, the transfer tray 715 is disposed in the vapor deposition chamber 111, is always stored in a vacuum, and is disposed near the substrate 700. Thus, while the transfer tray 715 is conveyed above the evaporation source 121, the getter member 704 can be uniformly formed on the transfer tray 715 in a vacuum. Thus, in the present embodiment, the getter member 704 can maintain its high adsorption capacity for contamination and can adsorb contamination, thereby effectively suppressing a decrease in luminance due to contamination.

Furthermore, when the getter member 704 is disposed on the transfer tray 715, and a plurality of the substrates 700 are subjected to vapor deposition, the getter member 704 can be formed on the transfer tray 715 each time before each of the substrates 700 is placed, that is, before each of the substrates 700 is fixed to the electrostatic chuck 713. Thus, for vapor deposition on each of the substrates 700, the getter member 704 can maintain its high adsorption capacity for contamination and can effectively suppress a decrease in luminance due to contamination of the substrates 700.

Although the getter member 704 in FIG. 44 is disposed in the entire area around each of the light-emitting region 102, the vapor deposition region 103, and the substrate 700, the getter member 704 may be disposed in one or two places around each of the light-emitting region 102, the vapor deposition region 103, and the substrate 700, as illustrated in FIG. 40 or 41. Although the getter member 704 in FIG. 44 is disposed on part of the exposed portion of the transfer tray 715, the getter member 704 may be disposed so as to evenly cover the entire exposed portion of the transfer tray 715.

The getter member 704 may include a portion evenly covering the entire exposed portion of the transfer tray 715 and a portion having an appropriately designed pattern. For example, the getter member 704 may include a lower layer portion having a pattern that evenly covers the entire exposed portion of the transfer tray 715 and an upper layer portion having an appropriately designed pattern on the lower layer portion.

The getter member 704 may have a flat surface but preferably has a rough surface as described in the second embodiment. In the same manner as in the second embodiment, a micropattern of the getter member 704 may be formed on the transfer tray 715 (the relative moving portion 712), and the getter member 704 may include many fine portions. This can increase the surface area of the getter member 704 and increase adsorption capacity for contamination, thus more effectively suppressing a decrease in luminance due to contamination.

The characteristic vapor deposition step in the seventh to ninth embodiments, that is, the vapor deposition step involving the use of the getter member 704 disposed on the relative moving portion 712 may be applied to a vapor deposition step other than the light-emitting layer deposition step S3, for example, the electron-transport layer deposition step S4. Likewise, the scanning deposition apparatuses according to the seventh to ninth embodiments may be used in a vapor deposition step other than the light-emitting layer deposition step S3, for example, the electron-transport layer deposition step S4. This can reduce contamination on the substrate 700 also in a vapor deposition step for an organic EL layer other than the light-emitting layer or a second electrode and can therefore more effectively suppress a decrease in luminance due to contamination. Furthermore, an organic EL layer other than the light-emitting layer can be formed in the sub-pixel of each color.

Other modified examples of the first to ninth embodiments will be described below.

An organic EL display apparatus according to the present embodiment may be a monochrome display apparatus, and each pixel may include no sub-pixels. In this case, in the light-emitting layer deposition step, only a light-emitting layer of one color may be formed by vapor deposition of a light-emitting material of one color alone.

In a vapor deposition step other than the light-emitting layer deposition step, a thin film pattern may be formed in the same manner as in the light-emitting layer deposition step. For example, an electron-transport layer may be formed for a sub-pixel of each color.

These embodiments may be combined if necessary without departing from the gist of the present invention. A modified example of one embodiment may be combined with another embodiment.

### REFERENCE SIGNS LIST

1: organic EL display apparatus
2: pixel
2R, 2G, 2B: sub-pixel
10: TFT substrate
11: insulating substrate
11a: main surface
12: TFT
13: interlayer film
13a: contact hole
14: electric wire
15: edge cover
15R, 15G, 15B: opening portion
20: organic EL device
21: first electrode
22: hole-injection and hole-transport layer (organic EL layer)
23R, 23G, 23B: light-emitting layer (organic EL layer)
24: electron-transport layer (organic EL layer)
25: electron-injection layer (organic EL layer)
26: second electrode
30: adhesive layer
40: sealing substrate
51, 54, 57: apparatus for manufacturing organic EL display apparatus (scanning deposition apparatus)
56: apparatus for manufacturing organic EL display apparatus (in-line deposition apparatus)
100, 500, 600, 700: organic EL display substrate
101: vapor deposition surface
102: light-emitting region
103: vapor deposition region
104, 704: getter member
105: micropattern
106, 140, 142: lower layer flat portion
107, 141, 143: upper layer portion
108: raised portion
109: recessed portion
110: vapor deposition unit
111: vapor deposition chamber (vacuum chamber)
121: evaporation source
122: diffusion unit
123: opening portion (ejection port)
130, 230, 330, 430: mask
131, 231, 232, 333, 431: opening
144, 145: pattern
150: getter substrate
151: insulating substrate
152: getter member
153: flat film
154: micropattern
160: vapor deposition flow
171, 172: conveying direction
180: contamination
712: relative moving portion
713: electrostatic chuck
714: anti-adhesion plate
715: transfer tray

1-26. (canceled)

27. An organic electroluminescent display substrate comprising:
a light-emitting region containing a plurality of pixels; and
a getter member to adsorb contamination, wherein the getter member is disposed in at least part of an area around the light-emitting region, and wherein
the getter member having a rough surface is formed of material used in a TFT or material used in an organic EL device.

28. The organic electroluminescent display substrate according to claim 27, wherein the getter member contains at least one material selected from the group consisting of aluminum (Al), copper (Cu), molybdenum (Mo), titanium (Ti), silicon (Si), silicon nitride, organic resins, positive electrode materials, hole-injection layer materials, hole-transport layer materials, and light-emitting layer materials.

29. The organic electroluminescent display substrate according to claim 27, wherein the getter member is disposed across a full width of the light-emitting region.

30. The organic electroluminescent display substrate according to claim 27, wherein the getter member is disposed in at least two portions of the area around the light-emitting region, the two portions facing each other with the light-emitting region interposed therebetween.

31. The organic electroluminescent display substrate according to claim 27, wherein the getter member is disposed in the entire area around the light-emitting region.

32. The organic electroluminescent display substrate according to claim 27, wherein
the organic electroluminescent display substrate includes a plurality of the light-emitting regions, and
the getter member is disposed in at least part of an area around each of the light-emitting regions.

33. The organic electroluminescent display substrate according to claim 27, wherein the organic electroluminescent display substrate has a micropattern of the getter member.

34. The organic electroluminescent display substrate according to claim 27, wherein the getter member is electrically insulated and is separated from the light-emitting region.

35. An organic electroluminescent display apparatus comprising the organic electroluminescent display substrate according to claim 27.

36. A method for manufacturing an organic electroluminescent display apparatus, comprising:
a vapor deposition step of depositing a material released from an evaporation source onto the organic electroluminescent display substrate according to claim 27 while conveying at least one of the organic electroluminescent display substrate and the evaporation source to move the organic electroluminescent display substrate relative to the evaporation source, the evaporation source being configured to vaporize and release the material,
wherein in the vapor deposition step, the at least one of the organic electroluminescent display substrate and the evaporation source is conveyed such that the getter member faces the evaporation source before the light-emitting region faces the evaporation source.

37. An apparatus for manufacturing an organic electroluminescent display apparatus comprising an evaporation source, the evaporation source being configured to vaporize and release a material,
wherein the manufacturing apparatus deposits the material released from the evaporation source onto the organic electroluminescent display substrate according to claim 27 while conveying at least one of the organic electroluminescent display substrate and the evaporation source to move the organic electroluminescent display substrate relative to the evaporation source, and conveys the at least one of the organic electroluminescent display substrate and the evaporation source such that the getter member faces the evaporation source before the light-emitting region faces the evaporation source.

38. The organic electroluminescent display substrate according to claim 27, wherein the getter member has a lower layer flat portion having a flat surface, and an upper layer portion disposed on the lower layer flat portion.

39. The organic electroluminescent display substrate according to claim 38, wherein the lower layer flat portion contains a gate line material, and the upper layer portion contains a signal line material.

40. The organic electroluminescent display substrate according to claim 38, wherein the lower layer flat portion contains a signal line material, and the upper layer portion contains silicon nitride

41. The organic electroluminescent display substrate according to claim 38, wherein the lower layer flat portion contains a signal line material, and the upper layer portion contains an organic resin material.

42. The organic electroluminescent display substrate according to claim 27, wherein the getter member includes a plurality of patterns.

43. The organic electroluminescent display substrate according to claim 42, wherein the plurality of patterns has different multilayer structures.

44. The organic electroluminescent display substrate according to claim 27, wherein one of the getter member is disposed in vapor deposition regions and another of the getter member is disposed in panel formation regions.

45. The organic electroluminescent display substrate according to claim 27, wherein a planar shape of the getter member is a curved shape.

46. A method for manufacturing an organic electroluminescent display apparatus according to claim 36, wherein the getter member is formed simultaneously with the formation of the organic EL device or the TFT.
